(19) United States
(12) Patent Application Publication
(10) Pub. No.: US 2017/0271380 A1
(43) Pub. Date: Sep. 21, 2017

(54) PEELING METHOD

(71) Applicant: Semiconductor Energy Laboratory Co., Ltd., Atsugi-shi (JP)

(72) Inventors: Seiji YASUMOTO, Tochigi (JP); Masataka SATO, Tochigi (JP); Masakatsu OHNO, Utsunomiya (JP); Hiroki ADACHI, Tochigi (JP)

(21) Appl. No.: 15/454,292

(22) Filed: Mar. 9, 2017

(30) Foreign Application Priority Data
Mar. 16, 2016 (JP) 2016-052041

(51) Int. Cl. H01L 27/12; H01L 21/683; H01L 51/56; H01L 21/02

(52) U.S. Cl. CPC H01L 27/1266; H01L 21/0217; H01L 21/02252; H01L 21/6835; H01L 21/02318; H01L 21/02164; H01L 21/02175; H01L 51/56; H01L 2221/68395; H01L 2251/566

(57) ABSTRACT

A peeling method of one embodiment of the present invention includes a first step of forming a first insulating layer over a substrate; a second step of forming a second insulating layer over the first insulating layer; a third step of forming a peeling layer over the second insulating layer; a fourth step of performing plasma treatment on a surface of the peeling layer; a fifth step of forming a third insulating layer over the peeling layer; a sixth step of performing heat treatment; and a seventh step of separating the peeling layer and the third insulating layer from each other. The first insulating layer and the third insulating layer each have a function of blocking hydrogen and for example, include a silicon nitride film or the like. The second insulating layer has a function of releasing hydrogen by heating and for example, includes a silicon oxide film.

### BACKGROUND OF THE INVENTION

1. Field of the Invention

One embodiment of the present invention relates to a peeling method and a method for fabricating a device including a peeling step.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a driving method thereof, and a manufacturing method thereof.

2. Description of the Related Art

In recent years, a flexible device in which a functional element such as a semiconductor element, a display element, or a light-emitting element is provided over a substrate having flexibility has been developed. Typical examples of the flexible device include a lighting device, an image display device, and a variety of semiconductor circuits including a semiconductor element such as a transistor.

As a method for manufacturing a device including a flexible substrate, a technique has been developed in which a functional element such as a thin film transistor or an organic electroluminescence (EL) element is formed over a formation substrate (e.g., a glass substrate or a quartz substrate), and then the functional element is transferred to a flexible substrate. This technique needs a step of peeling a layer including the functional element from the formation substrate (referred to as a peeling step).

For example, Patent Document 1 discloses the following peeling technique using laser ablation: a separation layer formed of amorphous silicon or the like is formed over a substrate, a layer to be peeled which includes a thin film element is formed over the separation layer, and the layer to be peeled is bonded to a transfer body with the use of a bonding layer. Then, the separation layer is ablated by laser light irradiation, so that peeling is caused in the separation layer.

In addition, Patent Document 2 discloses a technique in which peeling is conducted by physical force with human hands or the like. In Patent Document 2, a metal layer is formed between a substrate and an oxide layer and peeling is caused at an interface between the oxide layer and the metal layer by utilizing a weak bond between the oxide layer and the metal layer, and as a result, a layer to be peeled and the substrate are separated from each other.

### REFERENCE

### Patent Document

[Patent Document 1] Japanese Published Patent Application No. H10-125931

### [Patent Document 2] Japanese Published Patent Application No. 2003-174153

### SUMMARY OF THE INVENTION

An object of one embodiment of the present invention is to manufacture a flexible device that is repeatedly bendable. An object of one embodiment of the present invention is to manufacture a flexible device that can be bent with an extremely small radius of curvature.

An object of one embodiment of the present invention is to provide a novel peeling method. An object of one embodiment of the present invention is to manufacture, by using a peeling step, a device resistant to repetitive bending. An object of one embodiment of the present invention is to manufacture, by using a peeling step, a device that can be bent with an extremely small radius of curvature.

An object of one embodiment of the present invention is to improve a yield in a peeling step. An object of one embodiment of the present invention is to provide a peeling method with high peelability. An object of one embodiment of the present invention is to provide a method for manufacturing a device with high productivity.

Note that the descriptions of these objects do not disturb the existence of other objects. Note that one embodiment of the present invention does not necessarily achieve all the objects. Other objects can be derived from the description of the specification, the drawings, and the claims.

A peeling method of one embodiment of the present invention includes a first step of forming a first insulating layer over a substrate; a second step of forming a second insulating layer over the first insulating layer; a third step of forming a peeling layer over the second insulating layer; a fourth step of performing plasma treatment on a surface of the peeling layer; a fifth step of forming a third insulating layer over the peeling layer; a sixth step of performing heat treatment; and a seventh step of separating the peeling layer and the third insulating layer from each other.

In one embodiment of the present invention, the first insulating layer and the third insulating layer each have a function of blocking hydrogen. In one embodiment of the present invention, the first insulating layer and the third insulating layer each contain silicon and nitrogen.

In one embodiment of the present invention, the second insulating layer has a function of releasing hydrogen by heating. In one embodiment of the present invention, the second insulating layer contains silicon and oxygen.

It is preferable that the first insulating layer and the third insulating layer each contain silicon nitride.

It is preferable that the first insulating layer and the third insulating layer be formed under the same film formation condition.

It is preferable that the second insulating layer contain silicon oxynitride.

It is preferable that the plasma treatment be performed under an atmosphere containing nitrous oxide. It is preferable that the plasma treatment be performed under an atmosphere containing nitrous oxide and silane.

In the fourth step, the plasma treatment preferably forms a fourth insulating layer over the peeling layer.

In the fourth step, the plasma treatment preferably forms an oxide layer on the peeling layer. The oxide layer contains at least one of materials contained in the peeling layer.

In the third step, the peeling layer is preferably formed to contain tungsten. In the fourth step, the oxide layer is preferably formed to contain tungsten and oxygen by the plasma treatment.

According to one embodiment of the present invention, a flexible device that is repeatedly bendable can be manufactured. According to one embodiment of the present invention, a flexible device that can be bent with an extremely small radius of curvature can be manufactured.

According to one embodiment of the present invention, a novel peeling method can be provided. According to one embodiment of the present invention, a thin device can be manufactured by using a peeling step. The thin device can be resistant to repetitive bending. The thin device can be bent with an extremely small radius of curvature.

According to one embodiment of the present invention, a yield in a peeling step can be improved. According to one embodiment of the present invention, a peeling method with high peelability can be provided. According to one embodiment of the present invention, a method for manufacturing a device with high productivity can be provided.

Note that the descriptions of these effects do not disturb the existence of other effects. One embodiment of the present invention does not necessarily achieve all the effects. Other effects can be derived from the description of the specification, the drawings, and the claims.

### BRIEF DESCRIPTION OF THE DRAWINGS

FIGS. 1A to 1D are cross-sectional views illustrating an example of a peeling method.

FIGS. 2A to 2C are cross-sectional views illustrating an example of a peeling method.

FIGS. 3A to 3D are top views each illustrating an example of a light-emitting device.

FIG. 4 is a cross-sectional view illustrating an example of a light-emitting device.

FIGS. 5A to 5C are cross-sectional views illustrating an example of a method for manufacturing a light-emitting device.

FIGS. 6A and 6B are cross-sectional views illustrating an example of a method for manufacturing a light-emitting device.

FIGS. 7A and 7B are cross-sectional views illustrating an example of a method for manufacturing a light-emitting device.

FIGS. 8A and 8B are cross-sectional views each illustrating an example of a light-emitting device.

FIGS. 9A and 9B are cross-sectional views each illustrating an example of a light-emitting device.

FIGS. 10A and 10B are perspective views illustrating an example of a touch panel.

FIG. 11 is a cross-sectional view illustrating an example of a touch panel.

FIG. 12A is a cross-sectional view illustrating an example of a touch panel and FIGS. 12B to 12D are a top view and cross-sectional views of a transistor.

FIG. 13 is a cross-sectional view illustrating an example of a touch panel.

FIG. 14 is a cross-sectional view illustrating an example of a touch panel.

FIG. 15 is a cross-sectional view illustrating an example of a touch panel.

FIGS. 16A and 16B are perspective views illustrating an example of a touch panel.

FIG. 17 is a cross-sectional view illustrating an example of a touch panel.

FIGS. 18A and 18B are cross-sectional views each illustrating an example of a touch panel.

FIGS. 19A, 19B, 19C1, 19C2, 19D, 19E, 19F, 19G, and 19H illustrate examples of electronic devices and lighting devices.

FIGS. 20A1, 20A2, 20B, 20C, 20D, 20E, 20F, 20G, 20H, and 20I illustrate examples of electronic devices.

FIGS. 21A to 21E illustrate examples of electronic devices.

FIGS. 22A, 22B, and 22C respectively show TDS results of Sample A, Sample B, and Sample C in Example 1.

FIGS. 23A, 23B, and 23C respectively show TDS results of Sample A, Sample B, and Sample C in Example 1.

FIG. 24A is a perspective view illustrating a device used for measurement of force required for peeling in Example 2, FIG. 24B is a cross-sectional view illustrating Sample 1 in Example 2, and FIGS. 24C and 24D are cross-sectional views illustrating Comparative Sample 2 in Example 2.

### DETAILED DESCRIPTION OF THE INVENTION

Embodiments will be described in detail with reference to the drawings. Note that one embodiment of the present invention is not limited to the following description. It will be readily appreciated by those skilled in the art that modes and details of the present invention can be modified in various ways without departing from the spirit and scope of the present invention. Thus, the present invention should not be construed as being limited to the description in the following embodiments.

Note that in the structures of the present invention described below, the same portions or portions having similar functions are denoted by the same reference numerals in different drawings, and description of such portions is not repeated. Further, the same hatching pattern is applied to portions having similar functions, and the portions are not especially denoted by reference numerals in some cases.

The position, size, range, or the like of each component illustrated in drawings is not accurately represented in some cases for easy understanding. Therefore, the disclosed invention is not necessarily limited to the position, size, range, or the like disclosed in the drawings.

Note that the terms “film” and “layer” can be interchanged with each other depending on the case or circumstances. For example, the term “conductive layer” can be changed into the term “conductive film”. Also, the term “insulating film” can be changed into the term “insulating layer”.

In this specification and the like, “silicon oxynitride” includes oxygen at a higher proportion than nitrogen, and “silicon nitride oxide” includes nitrogen at a higher proportion than oxygen.

### Embodiment 1

In this embodiment, a peeling method of one embodiment of the present invention will be described.

In one embodiment of the present invention, a first insulating layer is formed over a substrate, a second insulating layer is formed over the first insulating layer, a peeling layer is formed over the second insulating layer, plasma treatment is performed on a surface of the peeling layer, a third insulating layer is formed over the peeling layer that has been subjected to the plasma treatment, heat treatment is performed and then, the peeling layer and the third insulating layer are separated from each other.

A functional element can be formed over the third insulating layer. In that case, by separating the peeling layer and the third insulating layer from each other, the functional element can be separated from the substrate and transferred to a flexible substrate. Accordingly, a flexible device can be manufactured.

The first insulating layer and the third insulating layer each have a function of blocking hydrogen. The second insulating layer has a function of releasing hydrogen by heating.

The plasma treatment performed on a surface of the peeling layer changes the state of the surface of the peeling layer. By the heat treatment following the plasma treatment, hydrogen is released from the second insulating layer and then supplied to a region where the state of the peeling layer has been changed. Since the first insulating layer and the third insulating layer each have a function of blocking hydrogen, hydrogen released from the second insulating layer does not easily pass through the first insulating layer and the third insulating layer. Thus, hydrogen can be efficiently supplied to the region where the state of the peeling layer has been changed.

For example, by performing plasma treatment under the atmosphere containing nitrous oxide (N₂O), the surface of the peeling layer is oxidized, so that an oxide layer is formed. The oxide layer includes an oxide of a material contained in the peeling layer. In the case where tungsten is included in the peeling layer, an oxide layer containing tungsten oxide can be formed.

Hydrogen is released from the second insulating layer by the heat treatment, whereby hydrogen is supplied to the oxide layer.

The second insulating layer may release not only hydrogen but also nitrogen by the heating. When nitrogen is released from the second insulating layer by the heat treatment, nitrogen is supplied to the oxide layer.

The first insulating layer and the third insulating layer may each have a function of blocking hydrogen and nitrogen. In that case, hydrogen and nitrogen released from the second insulating layer can be prevented from passing through the first insulating layer and the third insulating layer. Thus, hydrogen and nitrogen can be efficiently supplied to the oxide layer.

The oxide in the oxide layer is reduced by hydrogen supplied to the oxide layer, so that plural kinds of oxides with different proportions of oxygen are mixed in the oxide layer. For example, in the case where tungsten is included in the peeling layer, WO₃ formed by plasma treatment is reduced to generate WOₓ (2<x<3) and WO₂ with proportion of oxygen lower than that of WO₃, leading to a state where WO₃ and the oxides with lower proportions of oxygen are mixed. The crystal structure of such a mixed metal oxide depends on the proportion of oxygen; thus, the mechanical strength of the oxide layer is reduced. As a result, the oxide layer is likely to be damaged inside, so that the peelability in a later peeling step can be improved.

In addition, a compound containing nitrogen and a material in the peeling layer is generated by nitrogen supplied to the oxide layer. Such a compound further reduces the mechanical strength of the oxide layer, so that the peelability can be improved. In the case where a metal is included in the peeling layer, a compound (a metal nitride) containing the metal and nitrogen is generated in the oxide layer. For example, in the case where tungsten is included in the peeling layer, tungsten nitride is generated in the oxide layer.

The larger the amount of hydrogen supplied to the oxide layer, the likelier it becomes that WO₃ is reduced and that the state where plural kinds of oxides with different proportions of oxygen are mixed in the oxide layer is formed. Therefore, the force required for the peeling can be reduced. The larger the amount of nitrogen supplied to the oxide layer, the more the mechanical strength of the oxide layer can be reduced and the force required for the peeling can be reduced.

The thicker a layer having a function of releasing hydrogen (and nitrogen), the more the layer releases hydrogen (and nitrogen).

In the case where a layer having a function of releasing hydrogen (and nitrogen) is provided between the peeling layer and the third insulating layer, the layer having a function of releasing hydrogen (and nitrogen) is a component of the flexible device. When the flexible device has a large thickness, it is sometimes difficult to bend the flexible device repeatedly or bend it with an extremely small radius of curvature. In the stacked-layer structure of the flexible device, a layer farther from the neutral plane (a plane where no stress distortion occurs or a plane that does not expand and contract) is subjected to greater stress because of bending and is more likely to be damaged.

In one embodiment of the present invention, the second insulating layer is provided between the substrate and the peeling layer. The second insulating layer is not a component of the flexible device and thus can have a large thickness. When the second insulating layer is configured to release a sufficient amount of hydrogen, the layer to be peeled does not need to be provided with a layer having a function of releasing hydrogen (and nitrogen). The thickness of the layer to be peeled (and the thickness of the flexible device) can be small and peeling can be performed with a high yield. The reduction in thickness of the flexible device itself can inhibit great stress due to bending and inhibit damage to the flexible device.

Since the peeling method of one embodiment of the present invention includes a step of changing the state of a surface of the peeling layer that is in contact with the third insulating layer, peeling can be performed reliably between the peeling layer and the third insulating layer, not between the second insulating layer and the peeling layer.

As examples of devices that can be manufactured by the peeling method of one embodiment of the present invention, a semiconductor device, a display device, a light-emitting device, an input/output device, and the like can be given. Examples of a display element included in a display device include a light-emitting element such as an inorganic EL element, an organic EL element, or an LED, a liquid crystal element, an electrophoretic element, and a display element using micro electro mechanical systems (MEMS).

When one embodiment of the present invention is utilized, a semiconductor device, a light-emitting device, a display device, an input/output device, and the like can be made thin, lightweight, and flexible. Moreover, a flexible device that is repeatedly bendable or a flexible device that can be bent with an extremely small radius of curvature can be manufactured.

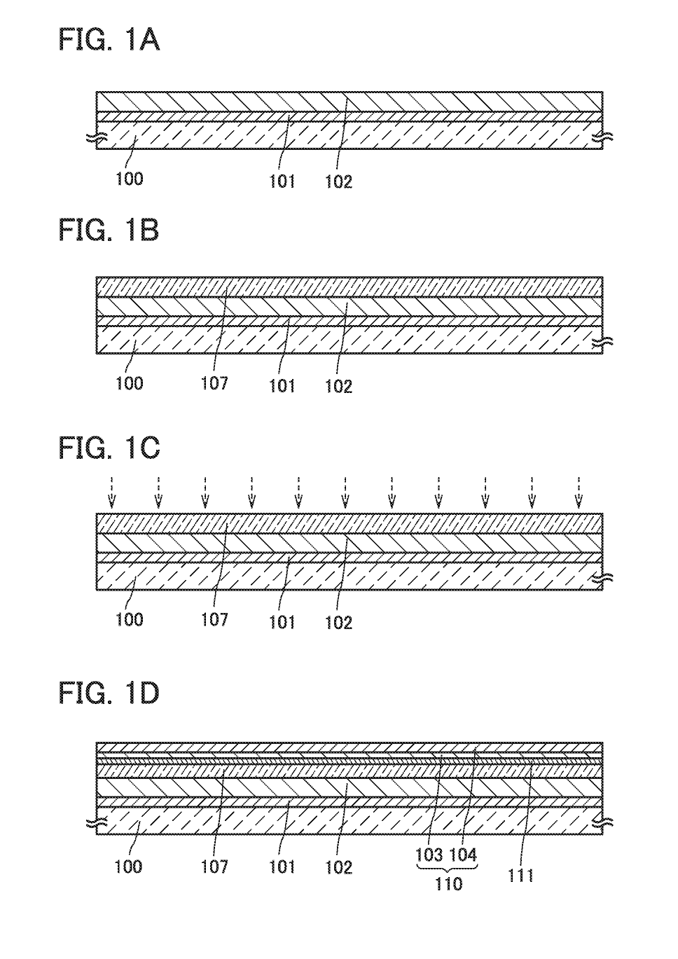

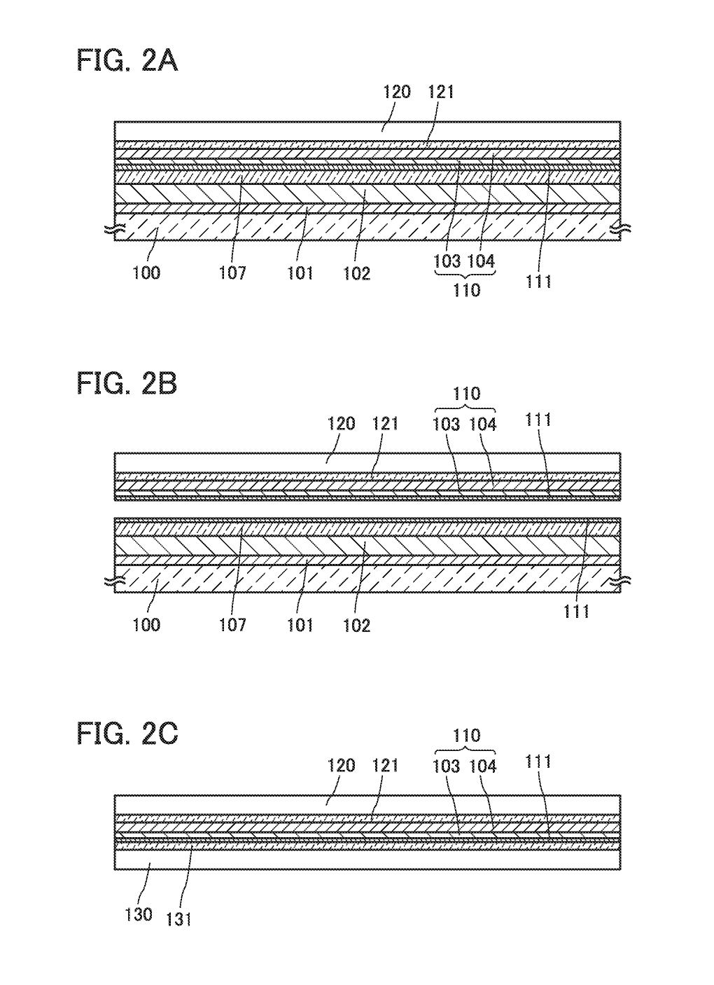

Hereinafter, the peeling method of one embodiment of the present invention is described with reference to FIGS. 1A to 1D and FIGS. 2A to 2C. Note that although an oxide layer is illustrated in drawings used for the explanation in this embodiment (see an oxide layer 111 illustrated in FIG. 1D or the like), the oxide layer formed in one embodiment of the present invention is extremely thin. Therefore, the oxide layer cannot be easily found by visual recognition or cross-sectional observation in some cases.

### [First Step]

First, a first insulating layer 101 is formed over a formation substrate 100 (FIG. 1A).

As the formation substrate 100, a substrate having at least heat resistance high enough to withstand process temperature in a fabrication process is used. As the formation substrate 100, for example, a glass substrate, a quartz substrate, a sapphire substrate, a semiconductor substrate, a ceramic substrate, a metal substrate, or a plastic substrate can be used.

It is preferable to use a large-sized glass substrate as the formation substrate 100 in order to increase the productivity. For example, a glass substrate having a size greater than or equal to the 3rd generation (550 mm×650 mm) and less than or equal to the 10th generation (2950 mm×3400 mm) or a glass substrate having a larger size than the 10th generation is preferably used.

The first insulating layer 101 preferably contains nitrogen and silicon. As the first insulating layer 101, for example, a silicon nitride film, a silicon oxynitride film, or a silicon nitride oxide film can be used. In particular, a silicon nitride film or a silicon nitride oxide film is preferably used.

The first insulating layer 101 has a function of blocking the hydrogen (and nitrogen) released from a second insulating layer 102 in a later heating step.

The first insulating layer 101 can be formed by a sputtering method, a plasma chemical vapor deposition (CVD) method, or the like. For example, a silicon nitride film included in the first insulating layer 101 is formed by a plasma CVD method using a deposition gas containing a silane gas, a hydrogen gas, and an ammonia (NH₃) gas.

The thickness of the first insulating layer 101 is not particularly limited. The thickness can be, for example, greater than or equal to 50 nm and less than or equal to 600 nm, preferably greater than or equal to 100 nm and less than or equal to 300 nm.

The absolute value of the stress applied on the first insulating layer 101 is preferably smaller, in which case a warp in the formation substrate 100 can be inhibited more. The absolute value of the stress applied on the first insulating layer 101 is preferably greater than or equal to 0 Pa and less than or equal to 500 MPa, further preferably greater than or equal to 0 Pa and less than or equal to 100 MPa. When a warp in the formation substrate 100 is reduced, the formation substrate 100 can be easily transferred even if it has a large size.

The absolute value of the stress applied on the stacked-layer structure formed over the substrate 100 is preferably smaller, in which case a warp in the formation substrate 100 can be inhibited more. The absolute value of the stress applied on the stacked-layer structure is preferably greater than or equal to 0 Pa and less than or equal to 500 MPa, further preferably greater than or equal to 0 Pa and less than or equal to 100 MPa.

Note that in the case where the formation substrate 100 has a sufficiently high blocking property against hydrogen (and nitrogen), the first insulating layer 101 does not always need to be provided. In that case, the second insulating layer 102 may be provided on and in contact with the formation substrate 100.

### [Second Step]

Next, the second insulating layer 102 is formed over the first insulating layer 101 (FIG. 1A).

As the second insulating layer 102, for example, a silicon oxide film, a silicon nitride film, a silicon oxynitride film, or a silicon nitride oxide film can be used. The second insulating layer 102 preferably contains oxygen and silicon. It is preferred that the second insulating layer 102 further contain nitrogen.

It is preferred that the second insulating layer 102 further contain hydrogen. The second insulating layer 102 has a function of releasing hydrogen in the later heating step. The second insulating layer 102 may further have a function of releasing hydrogen and nitrogen in the later heating step.

The second insulating layer 102 preferably includes a region where a hydrogen concentration measured by secondary ion mass spectrometry (SIMS) is higher than or equal to 1.0×10²⁰ atoms/cm³ and lower than or equal to 1.0×10²² atoms/cm³, further preferably higher than or equal to 5.0×10²⁰ atoms/cm³ and lower than or equal to 5.0×10²¹ atoms/cm³.

The second insulating layer 102 preferably includes a region where a nitrogen concentration measured by SIMS is higher than or equal to 5.0×10²⁰ atoms/cm³ and lower than or equal to 1.0×10²³ atoms/cm³, further preferably higher than or equal to 1.0×10²¹ atoms/cm³ and lower than or equal to 5.0×10²² atoms/cm³.

The second insulating layer 102 can be formed by a sputtering method, a plasma CVD method, or the like. In particular, the silicon oxynitride film included in the second insulating layer 102 is preferably formed by a plasma CVD method using a deposition gas containing a silane gas and a nitrous oxide gas, in which case a large amount of hydrogen and nitrogen can be contained in the film. In addition, the proportion of the silane gas in the deposition gas is preferably higher, in which case the amount of released hydrogen in the later heating step is increased.

The thickness of the second insulating layer 102 is preferably larger for an increase in the amount of released hydrogen and nitrogen; however, the thickness is preferably determined in consideration of productivity. The thickness of the second insulating layer 102 is preferably greater than or equal to 1 nm and less than or equal to 1 μm, further preferably greater than or equal to 50 nm and less than or equal to 800 nm, still further preferably greater than or equal to 100 nm and less than or equal to 600 nm, particularly preferably greater than or equal to 200 nm and less than or equal to 400 nm.

The absolute value of the stress applied on the second insulating layer 102 is preferably smaller, in which case a warp in the formation substrate 100 can be inhibited more. The absolute value of the stress applied on the second insulating layer 102 is preferably greater than or equal to 0 Pa and less than or equal to 500 MPa, further preferably greater than or equal to 0 Pa and less than or equal to 100 MPa.

At least one of the first insulating layer 101 and the second insulating layer 102 can serve as a base film. In the case where a glass substrate is used as the formation substrate 100, for example, a base film is preferably provided between the formation substrate 100 and a peeling layer 107 because contamination from the glass substrate can be prevented.

Another layer may be provided between the first insulating layer 101 and the second insulating layer 102.

### [Third Step]

Next, the peeling layer 107 is formed over the second insulating layer 102 (FIG. 1B).

An inorganic material can be used for the peeling layer 107. Examples of the inorganic material include a metal, an alloy, a compound, and the like that contain any of the following elements: tungsten (W), molybdenum (Mo), titanium, tantalum, niobium, nickel, cobalt, zirconium, zinc, ruthenium, rhodium, palladium, osmium, iridium, and silicon. A crystal structure of a layer containing silicon may be amorphous, microcrystal, or polycrystal.

The peeling layer 107 is preferably formed using a high-melting-point metal such as tungsten, titanium, or molybdenum, in which case the degree of freedom of the process for forming a layer 110 to be peeled can be increased.

In the case where the peeling layer 107 has a single-layer structure, a tungsten layer, a molybdenum layer, or a layer containing a mixture of tungsten and molybdenum is preferably formed. A mixture of tungsten and molybdenum is an alloy of tungsten and molybdenum, for example. For example, an alloy film of molybdenum and tungsten with an atomic ratio of Mo:W=3:1, 1:1, or 1:3 may be used. The alloy film of molybdenum and tungsten can be formed by a sputtering method using a metal target with a composition of Mo:W=49:51, 61:39, or 14.8:85.2 (wt %), for example.

The peeling layer 107 can be formed by, for example, a sputtering method, a CVD method (e.g., a plasma CVD method, a thermal CVD method, or a metal organic CVD (MOCVD) method), an atomic layer deposition (ALD) method, a coating method (e.g., a spin coating method, a droplet discharge method, or a dispensing method), a printing method, or an evaporation method.

The thickness of the peeling layer 107 is greater than or equal to 1 nm and less than or equal to 1000 nm, preferably greater than or equal to 10 nm and less than or equal to 200 nm, further preferably greater than or equal to 10 nm and less than or equal to 100 nm.

In this embodiment, the peeling layer 107 is formed using tungsten.

Note that the peeling layer 107 and the second insulating layer 102 are not necessarily in contact with each other, and another layer may be provided between the peeling layer 107 and the second insulating layer 102.

### [Fourth Step]

Next, plasma treatment is performed on a surface of the peeling layer 107 (see the arrows indicated by dotted lines in FIG. 1C).

The adhesion between the peeling layer 107 and the layer 110 to be peeled which is formed later can be controlled by changing the state of the surface of the peeling layer 107.

The plasma treatment is preferably performed under the atmosphere containing nitrous oxide. In that case, the surface of the peeling layer 107 is oxidized so that the oxide layer 111 of a material included in the peeling layer 107 can be formed on the peeling layer 107 (FIG. 1D).

The plasma treatment is preferably performed under the atmosphere containing nitrous oxide and silane. By this method, the oxide layer 111 with a very small thickness can be formed. The oxide layer 111 may be formed in a thin film such that the cross section thereof cannot be easily observed with an electron microscope or the like. When the oxide layer 111 is very thin, a decrease in light extraction efficiency of the light-emitting device or the display device can be suppressed. Alternatively, variation in the characteristics of the semiconductor element can be suppressed.

When plasma treatment is performed under the atmosphere containing nitrous oxide and silane in the fourth step, a film (e.g., a silicon oxynitride film or a silicon nitride oxide film) is sometimes formed over the peeling layer 107 by silane at the same time as the surface of the peeling layer 107 is oxidized by nitrous oxide. For example, during the plasma treatment, an insulating layer with a thickness of greater than or equal to 1 nm and less than or equal to 20 nm may be formed. In the case where the insulating layer is formed over the peeling layer 107 during the plasma treatment, oxidization of the peeling layer 107 is controlled. In that case, the oxide layer 111 with a small thickness can be formed on the peeling layer 107.

Note that the existence of oxide (and nitride) can be confirmed by analyzing, after the peeling layer 107 and the layer 110 to be peeled are separated from each other, the exposed surface of the peeling layer 107 or the exposed surface of the peeled layer 110 using X-ray photoelectron spectroscopy (XPS) or the like. That is, even if the oxide layer 111 cannot be easily found in the cross section observed with an electron microscope or the like, the oxide layer 111 can be observed by XPS or the like.

The plasma treatment is preferably performed under an atmosphere containing nitrous oxide, silane, and ammonia. In that case, the amount of hydrogen and nitrogen that are supplied from the second insulating layer 102 to the peeling layer 107 (or the oxide layer 111) can be reduced. This is presumably because the plasma treatment performed under the atmosphere not only forms the oxide layer 111 but also can supply hydrogen and nitrogen to the oxide layer 111. Accordingly, the thickness of the second insulating layer 102 can be reduced and the productivity can be improved.

Instead of the above plasma treatment, thermal oxidation treatment, oxygen plasma treatment, or treatment using a solution with high oxidizability such as ozone water may be used to form the oxide layer 111.

The oxide layer 111 contains an oxide of the material contained in the peeling layer. In the case where a metal is contained in the peeling layer 107, the oxide layer 111 contains an oxide of the metal contained in the peeling layer 107. The oxide layer 111 preferably contains tungsten oxide, titanium oxide, or molybdenum oxide.

Tungsten oxide is generally represented by WOₓ (2≦x<3) and can exist as a non-stoichiometric compound which can have a variety of compositions, typically WO₃, W₂O₅, W₄O₁₁, and WO₂. Titanium oxide and molybdenum oxide are also capable of existing as non-stoichiometric compounds.

In this embodiment, the oxide layer 111 contains tungsten oxide.

The thickness of the oxide layer 111 is greater than or equal to 1 nm and less than or equal to 15 nm, preferably greater than or equal to 1 nm and less than 5 nm, further preferably greater than or equal to 1 nm and less than or equal to 3 nm. The thickness of the oxide layer 111 may be less than 1 nm. As described above, the oxide layer 111 with an extremely small thickness is not easily observed in a cross-sectional image.

The oxide layer 111 at this stage preferably contains a large amount of oxygen. For example, in the case where tungsten is used for the peeling layer 107, the oxide layer 111 is preferably a tungsten oxide layer containing WO₃ as its main component.

Since the oxide layer 111 is formed by the plasma treatment in one embodiment of the present invention, the thickness of the oxide layer 111 can vary depending on the conditions for the plasma treatment. Note that in one embodiment of the present invention, disilane or trisilane may be used instead of silane.

### [Fifth Step]

Next, the layer 110 to be peeled is formed over the peeling layer 107 (or the oxide layer 111). In this embodiment, a third insulating layer 103 and an element layer 104 are formed as the layer 110 to be peeled (FIG. 1D).

The third insulating layer 103 preferably contains nitrogen and silicon.

The third insulating layer 103 has a function of blocking the hydrogen (and nitrogen) released from the second insulating layer 102 in the later heating step.

A material and a film formation method that can be used for the third insulating layer 103 are similar to those that can be used for the first insulating layer 101. The first insulating layer 101 and the third insulating layer 103 may be formed under the same film formation conditions.

The thickness of the third insulating layer 103 is not particularly limited. The thickness can be, for example, greater than or equal to 50 nm and less than or equal to 600 nm, preferably greater than or equal to 100 nm and less than or equal to 300 nm.

The absolute value of the stress applied on the third insulating layer 103 is preferably smaller, in which case a warp in the formation substrate 100 can be inhibited more. The absolute value of the stress applied on the third insulating layer 103 is preferably greater than or equal to 0 Pa and less than or equal to 500 MPa, further preferably greater than or equal to 0 Pa and less than or equal to 100 MPa.

Note that the oxide layer 111 and the third insulating layer 103 are not necessarily in contact with each other, and another layer may be provided between the oxide layer 111 and the third insulating layer 103.

The layer 110 to be peeled may include an insulating layer in addition to the third insulating layer 103.

The layer 110 to be peeled may include a functional element. The functional element can be formed over the third insulating layer 103 (in this embodiment, the functional element is called the element layer 104). In the case where one embodiment of the present invention is applied to, for example, a flexible device including a transistor, the transistor is formed over the third insulating layer 103.

There may be a step of fabricating a functional element between the sixth step and the seventh step. In the case where the functional element is fabricated after heat treatment, the heat resistance of the functional element is not limited by the heat treatment.

### [Sixth Step]

Next, heat treatment is performed, whereby the layers formed over the formation substrate 100 before the sixth step are heated.

By the heat treatment, hydrogen (and nitrogen) is released from the second insulating layer 102 and then supplied to the oxide layer 111. At this time, the first insulating layer 101 and the third insulating layer 103 block the released hydrogen (and nitrogen); thus, hydrogen (and nitrogen) can be efficiently supplied to the oxide layer 111.

The heat treatment is performed at a temperature higher than or equal to the temperature at which hydrogen (and nitrogen) is released from the second insulating layer 102 and lower than or equal to the temperature at which the formation substrate 100 is softened. The heat treatment is preferably performed at a temperature greater than or equal to the temperature at which the reduction of the metal oxide in the oxide layer 111 with hydrogen occurs. An increase in temperature of the heat treatment increases the amount of the released hydrogen (and nitrogen) from the second insulating layer 102, leading to improved peelability. Note that depending on heating temperature and heating time, the peelability is unnecessarily increased so that peeling occurs at an unintended timing. Thus, in the case where tungsten is used for the peeling layer 107, the heating temperature is higher than or equal to 300° C. and lower than 700° C., preferably higher than or equal to 400° C. and lower than 650° C., further preferably higher than or equal to 400° C. and lower than or equal to 500° C.

The atmosphere under which the heat treatment is performed is not particularly limited and may be an air atmosphere, and it is preferably performed under an inert gas atmosphere such as a nitrogen atmosphere or a rare gas atmosphere.

Hydrogen and nitrogen released from the layer 110 to be peeled by the heat treatment are trapped between the third insulating layer 103 and the peeling layer 107. As a result, a region with a high hydrogen concentration and a high nitrogen concentration is formed in the oxide layer 111. For example, a region in which a hydrogen concentration measured by SIMS is higher than that of the second insulating layer 102 is formed in the oxide layer 111. Alternatively, a region in which a nitrogen concentration measured by SIMS is higher than that of the second insulating layer 102 is formed in the oxide layer 111.

After the heat treatment, the absolute value of the stress applied on the stacked-layer structure including the first insulating layer 101, the second insulating layer 102, and the third insulating layer 103 is preferably smaller, in which case a warp in the formation substrate 100 can be inhibited more. The absolute value of the stress applied on the stacked-layer structure is preferably greater than or equal to 0 Pa and less than or equal to 500 MPa, further preferably greater than or equal to 0 Pa and less than or equal to 100 MPa, still further preferably greater than or equal to 0 Pa and less than or equal to 30 MPa. Tensile stress is preferably applied on the stacked-layer structure because smaller force is required for peeling. Compressive stress is preferably applied on the stacked-layer structure because a crack can be inhibited from being caused in the stacked-layer structure at the time of peeling.

Next, the formation substrate 100 and a substrate 120 are bonded to each other by a bonding layer 121 (FIG. 2A).

As the substrate 120, various substrates that can be used as the formation substrate 100 can be used. Alternatively, a flexible substrate may be used. Alternatively, as the substrate 120, a substrate provided with a functional element such as a semiconductor element (e.g., a transistor), a light-emitting element (e.g., an organic EL element), a liquid crystal element, or a sensor element, a color filter, and the like in advance may be used.

As the bonding layer 121, a variety of curable adhesives, e.g., photo-curable adhesives such as an ultraviolet curable adhesive, a reactive curable adhesive, a thermosetting adhesive, and an anaerobic adhesive can be used. Alternatively, as the bonding layer 121, an adhesive which allows separation between the substrate 120 and the layer 110 to be peeled when necessary, such as a water-soluble resin, a resin soluble in an organic solvent, or a resin which is capable of being plasticized upon irradiation with ultraviolet light or the like may be used.

### [Seventh Step]

Then, the peeling layer 107 and the layer 110 to be peeled are separated from each other (FIG. 2B).

For the peeling, for example, the formation substrate 100 or the substrate 120 is fixed to a suction stage and a peeling trigger is formed between the peeling layer 107 and the layer 110 to be peeled. The peeling trigger may be formed by, for example, inserting a sharp instrument such as a knife between the layers. Alternatively, the peeling trigger may be formed by irradiating part of the peeling layer 107 with laser light to melt the part of the peeling layer 107. Further alternatively, the peeling trigger may be formed by dripping liquid (e.g., alcohol, water, or water containing carbon dioxide) onto an end portion of, for example, the peeling layer 107 or the layer 110 to be peeled so that the liquid penetrates into an interface between the peeling layer 107 and the layer 110 to be peeled by using capillary action.

Then, physical force (a peeling process with a human hand or with a gripper, a separation process by rotation of a roller, or the like) is gently applied to the area where the peeling trigger is formed in a direction substantially perpendicular to the bonded surfaces, so that peeling can be caused without damage to the layer 110 to be peeled. For example, peeling may be caused by attaching tape or the like to the formation substrate 100 or the substrate 120 and pulling the tape in the aforementioned direction, or peeling may be caused by pulling an end portion of the formation substrate 100 or the substrate 120 with a hook-like member. Alternatively, peeling may be caused by pulling an adhesive member or a member capable of vacuum suction attached to the back side of the formation substrate 100 or the substrate 120.

Here, when the peeling is performed in such a manner that liquid containing water such as water or an aqueous solution is added to the peeling interface at the time of the peeling and the liquid penetrates into the peeling interface, the peelability can be improved. Moreover, an adverse effect on the functional element included in the layer 110 to be peeled due to static electricity caused at the time of the peeling (e.g., a phenomenon in which a semiconductor element is damaged by static electricity) can be inhibited.

The peeling is mainly caused inside the oxide layer 111 and at the interface between the oxide layer 111 and the peeling layer 107. Thus, as illustrated in FIG. 2B, part of the oxide layer 111 could be attached to each of the surfaces of the peeling layer 107 and the third insulating layer 103 after the peeling. Note that the thickness of the oxide layer 111 attached to the surface of the peeling layer 107 may be different from that of the oxide layer 111 attached to the surface of the third insulating layer 103. Since peeling is easily caused at the interface between the oxide layer 111 and the peeling layer 107, the thickness of the oxide layer 111 attached on the third insulating layer 103 side is usually larger than that of the oxide layer 111 attached on the peeling layer 107 side. Since a very thin oxide layer is formed in one embodiment of the present invention, a decrease in light extraction efficiency of the light-emitting device or the display device can be inhibited even when part of the oxide layer 111 remains on the surface of the third insulating layer 103 after the peeling. Alternatively, a change in characteristics of the semiconductor element can be inhibited.

By the above method, the layer 110 to be peeled can be peeled from the formation substrate 100 with a high yield.

Then, a substrate 130 may be bonded to the peeling surface of the peeled layer 110 with a bonding layer 131 interposed therebetween (FIG. 2C). The bonding layer 131 can be formed using a material for the bonding layer 121. The substrate 130 can be formed using a material for the substrate 120.

By using flexible substrates as the substrates 120 and 130, a flexible stack can be formed. Note that in the case where the substrate 120 functions as a temporary supporting substrate, the substrate 120 and the layer 110 to be peeled are separated from each other, and the peeled layer 110 may be bonded to another substrate (for example, a flexible substrate).

Here, in the case where a material having a transmitting property with respect to visible light is used for the substrate 130 and the bonding layer 131, an average transmittance with respect to light in the wavelength range of 450 nm to 700 nm of a stack including the substrate 130, the bonding layer 131, the oxide layer 111, and the third insulating layer 103 is greater than or equal to 70% or greater than or equal to 80%. Note that another insulating layer included in the layer 110 to be peeled may be included in the stack.

As described above, in the peeling method of one embodiment of the present invention, the insulating layer (the second insulating layer) that has a function of releasing hydrogen by heating is formed between the formation substrate and the peeling layer. Accordingly, the layer to be peeled from the peeling layer can be thin. The state of the surface of the peeling layer that is in contact with the third insulating layer is changed by the plasma treatment or the like, whereby peeling can be reliably caused between the peeling layer and the third insulating layer, not between the peeling layer and the second insulating layer.

In the peeling method of one embodiment of the present invention, peeling is performed after the functional element is formed over the formation substrate, so that flexibility can be obtained; thus, there is almost no limitation on the temperature in formation steps of the functional element. Thus, a functional element with extremely high reliability which is manufactured through a high-temperature process can be manufactured over a flexible substrate with poor heat resistance with a high yield.

This embodiment can be combined with any other embodiment as appropriate.

### Embodiment 2

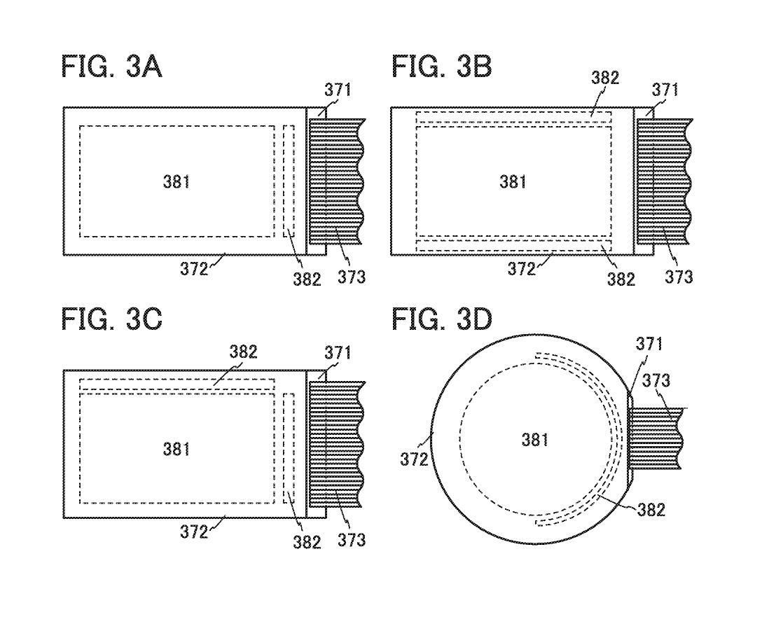

In this embodiment, light-emitting devices that can be manufactured by the peeling method of one embodiment of the present invention are described with reference to FIGS. 3A to 3D, FIG. 4, FIGS. 5A to 5C, FIGS. 6A and 6B, FIGS. 7A and 7B, FIGS. 8A and 8B, FIGS. 9A and 9B, FIGS. 10A and 10B, FIG. 11, FIGS. 12A to 12D, FIG. 13, FIG. 14, FIG. 15, FIGS. 16A and 16B, FIG. 17, and FIGS. 18A and 18B. In this embodiment, light-emitting devices including EL elements are described as examples. The light-emitting devices in this embodiment can each be manufactured by performing the peeling method of one embodiment of the present invention at least once.

Although a layer that corresponds to the oxide layer 111 illustrated in FIG. 1D and the like is not illustrated in the drawings used for the description in this embodiment, a light-emitting device using one embodiment of the present invention may include an oxide layer. Note that the oxide layer is extremely thin and sometimes cannot be easily found by visual recognition or cross-sectional observation.

FIGS. 3A to 3D each illustrate a light-emitting device including a pair of substrates (a substrate 371 and a substrate 372). The light-emitting device includes a light-emitting unit 381 and a driver circuit unit 382. An FPC 373 is connected to the light-emitting device. The FPC 373 is electrically connected to an external connection electrode (not illustrated) over the substrate 371.

In the light-emitting device illustrated in FIG. 3A, the driver circuit unit 382 is provided on one side.

In each of the light-emitting devices in FIGS. 3B and 3C, the driver circuit units 382 are provided on two sides. In FIG. 3B, the driver circuit units 382 are provided along two sides facing each other. In the light-emitting device illustrated in FIG. 3C, one of the driver circuit units 382 is provided along a short side and the other thereof is provided along a long side.

The light-emitting unit 381 does not necessarily have a polygonal top surface shape and may have any of a variety of top surface shapes such as circular and elliptical shapes. FIG. 3D illustrates an example of the light-emitting device in which the top surface shape of the light-emitting unit 381 is circular.

The light-emitting device does not necessarily have a polygonal top surface shape and may have any of a variety of top surface shapes such as circular and elliptical shapes. The light-emitting device in FIG. 3D has a top surface shape including both a curved portion and a linear portion.

### Structural Example 1

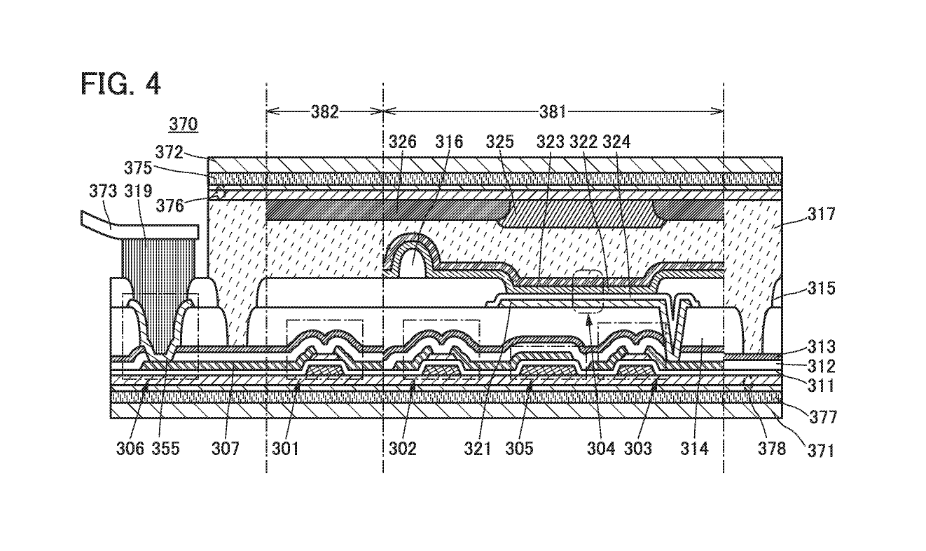

FIG. 4 is a cross-sectional view of a light-emitting device 370 employing a color filter method and having a top-emission structure.

In this embodiment, the light-emitting device can have, for example, a structure in which sub-pixels of three colors of red (R), green (G), and blue (B) express one color, a structure in which sub-pixels of four colors of red (R), green (G), blue (B), and white (W) express one color, or a structure in which sub-pixels of four colors of red (R), green (G), blue (B), and yellow (Y) express one color. The color element is not particularly limited and colors other than R, G, B, W, and Y may be used. For example, cyan, magenta, or the like may be used.

The light-emitting device 370 includes the substrate 371, a bonding layer 377, an insulating layer 378, a plurality of transistors, a capacitor 305, a conductive layer 307, an insulating layer 312, an insulating layer 313, an insulating layer 314, an insulating layer 315, a light-emitting element 304, a conductive layer 355, a spacer 316, a bonding layer 317, a coloring layer 325, a light-blocking layer 326, the substrate 372, a bonding layer 375, and an insulating layer 376.

FIG. 4 illustrates an example in which the insulating layer 376 and the insulating layer 378 each have a two-layer structure. Of the two layers included in the insulating layer 378, the layer on the bonding layer 377 side corresponds to the insulating layer in Embodiment 1 that is formed during the plasma treatment, and the layer on a gate insulating layer 311 side corresponds to the third insulating layer 103 described in Embodiment 1. Similarly, of the two layers included in the insulating layer 376, the layer on the bonding layer 375 side corresponds to the insulating layer in Embodiment 1 that is formed during the plasma treatment, and the layer on the bonding layer 317 side corresponds to the third insulating layer 103 described in Embodiment 1. Note that the structures of the insulating layer 376 and the insulating layer 378 are not limited to the above. The insulating layer 376 and the insulating layer 378 may each have a single-layer structure or a stacked-layer structure including three or more layers.

The driver circuit unit 382 includes a transistor 301. The light-emitting unit 381 includes a transistor 302 and a transistor 303.

Each transistor includes a gate, the gate insulating layer 311, a semiconductor layer, a source, and a drain. The gate and the semiconductor layer overlap with each other with the gate insulating layer 311 provided therebetween. Part of the gate insulating layer 311 functions as a dielectric of the capacitor 305. The conductive layer functioning as the source or the drain of the transistor 302 serves as one electrode of the capacitor 305.

In FIG. 4, bottom-gate transistors are illustrated. The structure of the transistor may differ between the driver circuit unit 382 and the light-emitting unit 381. The driver circuit unit 382 and the light-emitting unit 381 may each include a plurality of kinds of transistors.

The capacitor 305 includes a pair of electrodes and the dielectric therebetween. The capacitor 305 includes a conductive layer that is formed using the same material and the same step as the gates of the transistors and a conductive layer that is formed using the same material and the same step as the sources and the drains of the transistors.

The insulating layer 312, the insulating layer 313, and the insulating layer 314 are each provided to cover the transistors and the like. The number of the insulating layers covering the transistors and the like is not particularly limited. The insulating layer 314 functions as a planarization layer. It is preferable that at least one of the insulating layer 312, the insulating layer 313, and the insulating layer 314 be formed using a material inhibiting diffusion of impurities such as water or hydrogen. Diffusion of impurities from the outside into the transistors can be effectively inhibited, leading to improved reliability of the light-emitting device.

In the case where the insulating layer 314 is formed using an organic material, impurities such as moisture might enter the light-emitting element 304 and the like from the outside of the light-emitting device through the insulating layer 314 exposed at an end portion of the light-emitting device. Deterioration of the light-emitting element 304 due to the entry of an impurity leads to deterioration of the light-emitting device. Thus, as illustrated in FIG. 4, it is preferable that an opening which reaches an inorganic film (here, the insulating layer 313) be formed in the insulating layer 314 so that an impurity such as moisture entering from the outside of the light-emitting device does not easily reach the light-emitting element 304.

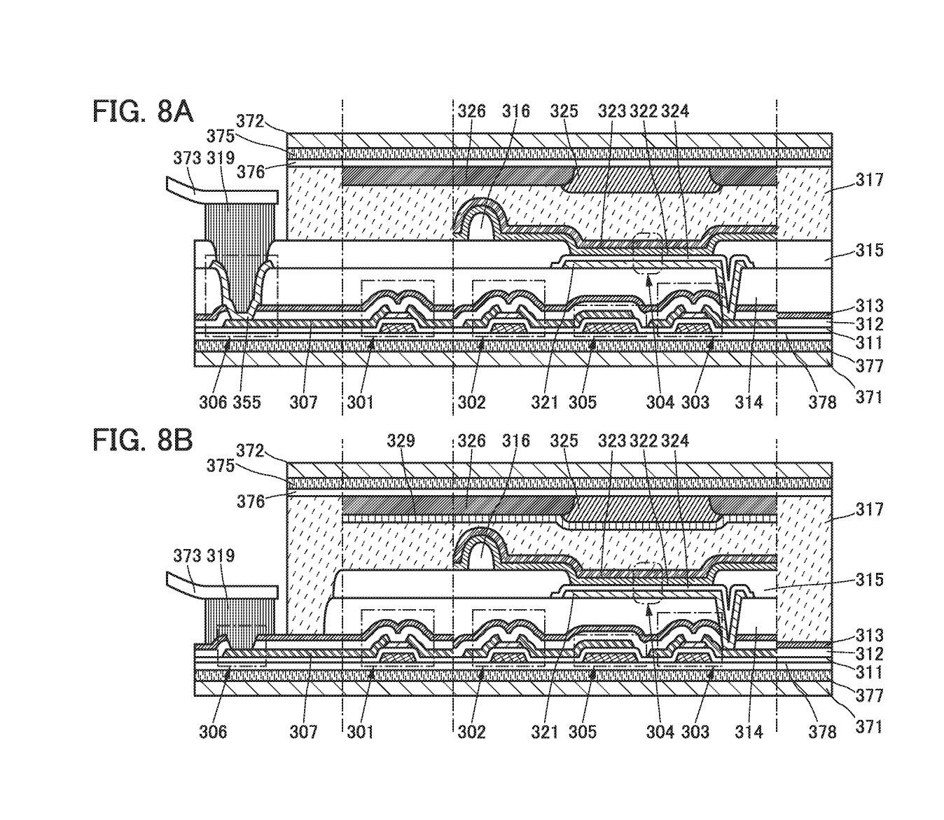

FIG. 8A is a cross-sectional view illustrating the case where the opening is not provided in the insulating layer 314. The insulating layer 314 is preferably provided in the entire area of the light-emitting device as illustrated in FIG. 8A, in which case the yield of the peeling step can be increased.

FIG. 8B is a cross-sectional view illustrating the case where the insulating layer 314 is not positioned at the end portion of the light-emitting device. Since an insulating layer formed using an organic material is not positioned at the end portion of the light-emitting device in the structure of FIG. 8B, entry of impurities into the light-emitting element 304 can be inhibited.

In FIGS. 8A and 8B, the insulating layer 376 and the insulating layer 378 each have a single-layer structure. Each of the insulating layer 376 and the insulating layer 378 corresponds to the third insulating layer 103 described in Embodiment 1. The insulating layer 376 and the insulating layer 378 can have structures similar to those illustrated in FIG. 4. Similarly, even when the insulating layer 376 and the insulating layer 378 each have a single-layer structure in the following structure examples, the insulating layer 376 and the insulating layer 378 can have structures similar to those illustrated in FIG. 4.

The light-emitting element 304 includes an electrode 321, an EL layer 322, and an electrode 323. The light-emitting element 304 may include an optical adjustment layer 324. The light-emitting element 304 has a top-emission structure with which light is emitted to the coloring layer 325 side.

The transistor, the capacitor, the wiring, and the like are provided to overlap with a light-emitting region of the light-emitting element 304, whereby an aperture ratio of the light-emitting unit 381 can be increased.

One of the electrode 321 and the electrode 323 functions as an anode and the other functions as a cathode. When a voltage higher than the threshold voltage of the light-emitting element 304 is applied between the electrode 321 and the electrode 323, holes are injected to the EL layer 322 from the anode side and electrons are injected to the EL layer 322 from the cathode side. The injected electrons and holes are recombined in the EL layer 322 and a light-emitting substance contained in the EL layer 322 emits light.

The electrode 321 is electrically connected to the source or the drain of the transistor 303 directly or through a conductive layer. The electrode 321 functions as a pixel electrode and is provided for each light-emitting element 304. Two adjacent electrodes 321 are electrically insulated from each other by the insulating layer 315.

The EL layer 322 is a layer containing a light-emitting substance.

The electrode 323 functions as a common electrode and is provided for a plurality of light-emitting elements 304. A fixed potential is supplied to the electrode 323.

The light-emitting element 304 and the coloring layer 325 overlap with each other with the bonding layer 317 positioned therebetween. The spacer 316 and the light-blocking layer 326 overlap with each other with the bonding layer 317 positioned therebetween. Although FIG. 4 illustrates the case where a space is provided between the electrode 323 and the light-blocking layer 326, the electrode 323 and the light-blocking layer 326 may be in contact with each other. Although the spacer 316 is provided on the substrate 371 side in the structure illustrated in FIG. 4, the spacer 316 may be provided on the substrate 372 side (e.g., in a position closer to the substrate 371 than that of the light-blocking layer 326).

Owing to the combination of a color filter (the coloring layer 325) and a microcavity structure (the optical adjustment layer 324), light with high color purity can be extracted from the light-emitting device. The thickness of the optical adjustment layer 324 is varied depending on the color of the pixel.

The coloring layer 325 is a coloring layer that transmits light in a specific wavelength range. For example, a color filter or the like that transmits light in a specific wavelength range, such as red, green, blue, or yellow light, can be used. As examples of a material that can be used for the coloring layer, a metal material, a resin material, a resin material containing a pigment or dye, and the like can be given.

Note that one embodiment of the present invention is not limited to a color filter method, and a separate coloring method, a color conversion method, a quantum dot method, or the like may be employed.

The light-blocking layer 326 is provided between adjacent coloring layers 325. The light-blocking layer 326 blocks light emitted from an adjacent light-emitting element to prevent color mixture between adjacent light-emitting elements. Here, the coloring layer 325 is provided such that its end portion overlaps with the light-blocking layer 326, whereby light leakage can be reduced. As the light-blocking layer 326, a material that can block light from the light-emitting element can be used; for example, a black matrix can be formed using a metal material or a resin material containing a pigment or dye. Note that it is preferable to provide the light-blocking layer 326 in a region other than a pixel portion, such as a driver circuit or the like, in which case undesired leakage of guided light or the like can be prevented.

In the example illustrated in FIG. 8B, an overcoat 329 is provided so as to cover the coloring layer 325 and the light-blocking layer 326. The overcoat 329 can prevent impurities and the like contained in the coloring layer 325 from being diffused into the light-emitting element. The overcoat 329 is formed with a material that transmits light emitted from the light-emitting element 304; for example, an inorganic insulating film such as a silicon nitride film or a silicon oxide film, or an organic insulating film such as an acrylic film or a polyimide film can be used, and further, a stacked-layer structure of an organic insulating film and an inorganic insulating film may be employed.

In the case where upper surfaces of the coloring layer 325 and the light-blocking layer 326 are coated with a material of the bonding layer 317, a material which has high wettability with respect to the material of the bonding layer 317 is preferably used as the material of the overcoat 329. For example, an oxide conductive film such as an ITO film or a metal film such as an Ag film which is thin enough to transmit light is preferably used as the overcoat 329.

When the overcoat 329 is formed using a material that has high wettability with respect to the material for the bonding layer 317, the material for the bonding layer 317 can be uniformly applied. Thus, entry of bubbles in the step of bonding the pair of substrates to each other can be prevented, and thus a display defect can be prevented.

The insulating layer 378 and the substrate 371 are bonded to each other with the bonding layer 377. The insulating layer 376 and the substrate 372 are bonded to each other with the bonding layer 375. The insulating layer 376 and the insulating layer 378 are preferably highly resistant to moisture. The light-emitting element 304, the transistors, and the like are preferably provided between a pair of insulating layers which are highly resistant to moisture, in which case impurities such as water can be prevented from entering these elements, leading to higher reliability of the light-emitting device.

Examples of the insulating layer highly resistant to moisture include a film containing nitrogen and silicon (e.g., a silicon nitride film and a silicon nitride oxide film) and a film containing nitrogen and aluminum (e.g., an aluminum nitride film). Alternatively, a silicon oxide film, a silicon oxynitride film, an aluminum oxide film, or the like may be used.

For example, the water vapor transmittance of the insulating layer highly resistant to moisture is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], and still further preferably lower than or equal to 1×10⁻⁸ [g/(m²·day)].

As described above, in FIG. 4, each of the insulating layer 376 and the insulating layer 378 includes a layer that corresponds to the third insulating layer 103 described in Embodiment 1. When a film containing nitrogen and silicon such as a silicon nitride film or a silicon nitride oxide film, an aluminum oxide film, or the like is used as the third insulating layer 103, the third insulating layer 103 can function as an insulating layer highly resistant to moisture.

A connection portion 306 includes the conductive layer 307 and the conductive layer 355. The conductive layer 307 and the conductive layer 355 are electrically connected to each other. The conductive layer 307 can be formed using the same material and the same step as those of the sources and the drains of the transistors. The conductive layer 355 is electrically connected to an external input terminal through which a signal or a potential from the outside is transmitted to the driver circuit unit 382. Here, an example in which an FPC 373 is provided as an external input terminal is shown. The FPC 373 and the conductive layer 355 are electrically connected to each other through a connector 319.

As the connector 319, any of various anisotropic conductive films (ACF), anisotropic conductive pastes (ACP), and the like can be used.

The substrates of the light-emitting device of one embodiment of the present invention preferably have flexibility. As the flexible substrates, a material that is thin enough to have flexibility, such as glass, quartz, a resin, a metal, an alloy, or a semiconductor, can be used. The substrate through which light is extracted from the light-emitting element is formed using a material which transmits the light. The thickness of the flexible substrate is preferably greater than or equal to 1 μm and less than or equal to 200 μm, further preferably greater than or equal to 1 μm and less than or equal to 100 μm, still further preferably greater than or equal to 10 μm and less than or equal to 50 μm, yet further preferably greater than or equal to 10 μm and less than or equal to 25 μm, for example. The thickness and hardness of the flexible substrate are set in the range where mechanical strength and flexibility can be balanced against each other. The flexible substrate may have a single-layer structure or a stacked-layer structure.

A resin, which has a specific gravity smaller than that of glass, is preferably used for the flexible substrate, in which case the light-emitting device can be lightweight as compared with the case where glass is used.

The substrate is preferably formed using a material with high toughness. In that case, a light-emitting device with high impact resistance that is less likely to be broken can be provided. For example, when a resin substrate or a thin metal or alloy substrate is used, the light-emitting device can be lightweight and robust as compared with the case where a glass substrate is used.

A metal material and an alloy material, which have high thermal conductivity, are each preferable because they can easily conduct heat to the whole substrate and accordingly can prevent a local temperature rise in the light-emitting device. The thickness of a substrate using a metal material or an alloy material is preferably greater than or equal to 10 μm and less than or equal to 200 μm, further preferably greater than or equal to 20 μm and less than or equal to 50 μm.

There is no particular limitation on a material of the metal substrate or the alloy substrate, but it is preferable to use, for example, aluminum, copper, nickel, or a metal alloy such as an aluminum alloy or stainless steel. Examples of a material for a semiconductor substrate include silicon and the like.

Furthermore, when a material with high thermal emissivity is used for the substrates, the surface temperature of the light-emitting device can be prevented from rising, leading to prevention of breakage and a decrease in reliability of the light-emitting device. For example, the substrate may have a stacked-layer structure of a metal substrate and a layer with high thermal emissivity (e.g., the layer can be formed using a metal oxide or a ceramic material).

Examples of materials with flexibility and a light-transmitting property include polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (such as nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and a cellulose nanofiber. In particular, a material with a low coefficient of linear expansion is preferred, and for example, a polyamide imide resin, a polyimide resin, a polyamide resin, or PET can be suitably used. Alternatively, a substrate in which a fibrous body is impregnated with a resin (also referred to as prepreg), a substrate whose coefficient of linear expansion is reduced by mixing a resin with an inorganic filler, or the like can be used.

The flexible substrate may have a structure in which a layer of any of the above-mentioned materials and at least one of a hard coat layer (e.g., a silicon nitride layer) by which a surface of the device is protected from damage or the like, a layer for dispersing pressure (e.g., an aramid resin layer), and the like are stacked. For example, a resin film may be provided between a pair of hard coat layers.

Any of a variety of curable adhesives, e.g., photo-curable adhesives such as an ultraviolet curable adhesive, a reactive curable adhesive, a thermosetting adhesive, and an anaerobic adhesive can be used for the bonding layer. Still alternatively, an adhesive sheet or the like may be used.

Furthermore, the bonding layer may include a drying agent. For example, it is possible to use a substance that adsorbs moisture by chemical adsorption, such as oxide of an alkaline earth metal (e.g., calcium oxide or barium oxide). Alternatively, a substance that adsorbs moisture by physical adsorption, such as zeolite or silica gel, may be used. The drying agent is preferably included because it can prevent an impurity such as moisture from entering the functional element, thereby improving the reliability of the light-emitting device.

When a filler with a high refractive index or a light scattering member is contained in the bonding layer, the efficiency of light extraction from the light-emitting element can be improved. For example, titanium oxide, barium oxide, zeolite, zirconium, or the like can be used.

As the light-emitting element, a self-luminous element can be used, and an element whose luminance is controlled by current or voltage is included in the category of the light-emitting element. For example, a light-emitting diode (LED), an organic EL element, an inorganic EL element, or the like can be used.

The light-emitting element may be a top-emission, bottom-emission, or dual-emission light-emitting element. A conductive film that transmits visible light is used as the electrode through which light is extracted. A conductive film that reflects visible light is preferably used as the electrode through which light is not extracted.

The conductive film that transmits visible light can be formed using, for example, indium oxide, ITO, indium zinc oxide, zinc oxide (ZnO), ZnO to which gallium is added, or the like. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be formed thin so as to have a light-transmitting property. Alternatively, a stack of any of the above materials can be used as the conductive film. For example, a stacked film of ITO and an alloy of silver and magnesium or the like is preferably used, in which case conductivity can be increased. Further alternatively, graphene or the like may be used.

For the conductive film that reflects visible light, for example, a metal material such as aluminum, gold, platinum, silver, nickel, tungsten, chromium, molybdenum, iron, cobalt, copper, or palladium or an alloy containing any of these metal materials can be used. Lanthanum, neodymium, germanium, or the like may be added to the metal material or the alloy. Furthermore, an alloy containing aluminum (an aluminum alloy) such as an alloy of aluminum and titanium, an alloy of aluminum and nickel, an alloy of aluminum and neodymium, or an alloy of aluminum, nickel, and lanthanum (Al—Ni—La); or an alloy containing silver such as an alloy of silver and copper, an alloy of silver, palladium, and copper (also referred to as Ag—Pd—Cu or APC), or an alloy of silver and magnesium may be used. An alloy containing silver and copper is preferable because of its high heat resistance. Furthermore, when a metal film or a metal oxide film is stacked in contact with an aluminum alloy film, oxidation of the aluminum alloy film can be inhibited. As examples of a material for the metal film or the metal oxide film, titanium, titanium oxide, and the like are given. Alternatively, the above conductive film that transmits visible light and a film containing a metal material may be stacked. For example, a stacked film of silver and ITO, a stacked film of an alloy of silver and magnesium and ITO, or the like can be used.

Each of the electrodes can be formed by an evaporation method or a sputtering method. Alternatively, a discharging method such as an inkjet method, a printing method such as a screen printing method, or a plating method may be used.

The EL layer 322 includes at least a light-emitting layer. The EL layer 322 may include a plurality of light-emitting layers. In addition to the light-emitting layer, the EL layer 322 may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

For the EL layer 322, either a low molecular compound or a high molecular compound can be used, and an inorganic compound may also be used. Each of the layers included in the EL layer 322 can be formed by any of the following methods: an evaporation method (including a vacuum evaporation method), a transfer method, a printing method, an inkjet method, a coating method, and the like.

The light-emitting element 304 may contain two or more kinds of light-emitting substances. Thus, for example, a light-emitting element that emits white light can be achieved. For example, light-emitting substances are selected so that two or more kinds of light-emitting substances emit complementary colors to obtain white light emission. A light-emitting substance that emits red (R) light, green (G) light, blue (B) light, yellow (Y) light, or orange (O) light or a light-emitting substance that emits light containing spectral components of two or more of R light, G light, and B light can be used, for example. A light-emitting substance that emits blue light and a light-emitting substance that emits yellow light may be used, for example. At this time, the emission spectrum of the light-emitting substance that emits yellow light preferably contains spectral components of G light and R light. The emission spectrum of the light-emitting element 304 preferably has two or more peaks in the wavelength range in a visible region (e.g., greater than or equal to 350 nm and less than or equal to 750 nm or greater than or equal to 400 nm and less than or equal to 800 nm).

Moreover, the light-emitting element 304 may be a single element including one EL layer or a tandem element in which EL layers are stacked with a charge generation layer provided therebetween.

In one embodiment of the present invention, a light-emitting element containing an inorganic compound such as a quantum dot may be employed. Examples of quantum dot materials include a colloidal quantum dot material, an alloyed quantum dot material, a core-shell quantum dot material, and a core quantum dot material. For example, an element such as cadmium (Cd), selenium (Se), zinc (Zn), sulfur (S), phosphorus (P), indium (In), tellurium (Te), lead (Pb), gallium (Ga), arsenic (As), or aluminum (Al) may be contained.

The structure of the transistors in the light-emitting device is not particularly limited. For example, a planar transistor, a staggered transistor, or an inverted staggered transistor may be used. A top-gate transistor or a bottom-gate transistor may be used. Gate electrodes may be provided above and below a channel.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

A semiconductor material used for the semiconductor layers of the transistors is not particularly limited, and for example, a Group 14 element, a compound semiconductor, or an oxide semiconductor can be used. Typically, a semiconductor containing silicon, a semiconductor containing gallium arsenide, an oxide semiconductor containing indium, or the like can be used.

An oxide semiconductor is preferably used as a semiconductor in which a channel of the transistor is formed. In particular, an oxide semiconductor having a wider band gap than silicon is preferably used. A semiconductor material having a wider band gap and a lower carrier density than silicon is preferably used because off-state current of the transistor can be reduced.

For example, the oxide semiconductor preferably contains at least indium (In) or zinc (Zn). The oxide semiconductor further preferably contains an In-M-Zn oxide (M is a metal such as Al, Ti, Ga, Ge, Y, Zr, Sn, La, Ce, Hf, or Nd).

A c-axis aligned crystalline oxide semiconductor (CAAC-OS) is preferably used as a semiconductor material for the transistors. Unlike an amorphous semiconductor, the CAAC-OS has few defect states, so that the reliability of the transistor can be improved. Moreover, since the CAAC-OS does not have a grain boundary, a stable and uniform film can be formed over a large area, and stress that is caused by bending a flexible light-emitting device does not easily make a crack in a CAAC-OS film.

A CAAC-OS is a crystalline oxide semiconductor having c-axis alignment of crystals in a direction substantially perpendicular to the film surface. It has been found that oxide semiconductors have a variety of crystal structures other than a single crystal structure. An example of such structures is a nano-crystal (nc) structure, which is an aggregate of nanoscale microcrystals. The crystallinity of a CAAC-OS structure is lower than that of a single crystal structure and higher than that of an nc structure.

As described above, the CAAC-OS has c-axis alignment, its pellets (nanocrystals) are connected in an a-b plane direction, and the crystal structure has distortion. For this reason, the CAAC-OS can also be referred to as an oxide semiconductor including a c-axis-aligned a-b-plane-anchored (CAA) crystal.

An organic insulating material or an inorganic insulating material can be used for the insulating layers included in the light-emitting device. Examples of resins include an acrylic resin, an epoxy resin, a polyimide resin, a polyamide resin, a polyimide-amide resin, a siloxane resin, a benzocyclobutene-based resin, and a phenol resin. Examples of an inorganic insulating film include a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film.

The conductive layers included in the light-emitting device can each have a single-layer structure or a stacked-layer structure including any of metals such as aluminum, titanium, chromium, nickel, copper, yttrium, zirconium, molybdenum, silver, tantalum, and tungsten or an alloy containing any of these metals as its main component. Alternatively, a light-transmitting conductive material such as indium oxide, ITO, indium oxide containing tungsten, indium zinc oxide containing tungsten, indium oxide containing titanium, ITO containing titanium, indium zinc oxide, ZnO, ZnO to which gallium is added, or indium tin oxide containing silicon may be used. Alternatively, a semiconductor such as an oxide semiconductor or polycrystalline silicon whose resistance is lowered by containing an impurity element or the like, or silicide such as nickel silicide may be used. A film including graphene may be used as well. The film including graphene can be formed, for example, by reducing a film containing graphene oxide. A semiconductor such as an oxide semiconductor containing an impurity element may be used. Alternatively, the conductive layers may be formed using a conductive paste of silver, carbon, copper, or the like or a conductive polymer such as a polythiophene. A conductive paste is preferable because it is inexpensive. A conductive polymer is preferable because it is easily applied.

### Example of Manufacturing Method of Structure Example 1

An example in which the light-emitting device illustrated in FIG. 4 is manufactured by the peeling method of one embodiment of the present invention is described below.

When the peeling method of one embodiment of the present invention is used, a component such as an insulating layer with high moisture resistance which is formed over a formation substrate at high temperature can be transferred to a flexible substrate. Therefore, even when an organic resin with low moisture resistance and low heat resistance or the like is used for the substrate in order to increase the flexibility of the light-emitting device, a light-emitting device with high reliability can be manufactured.

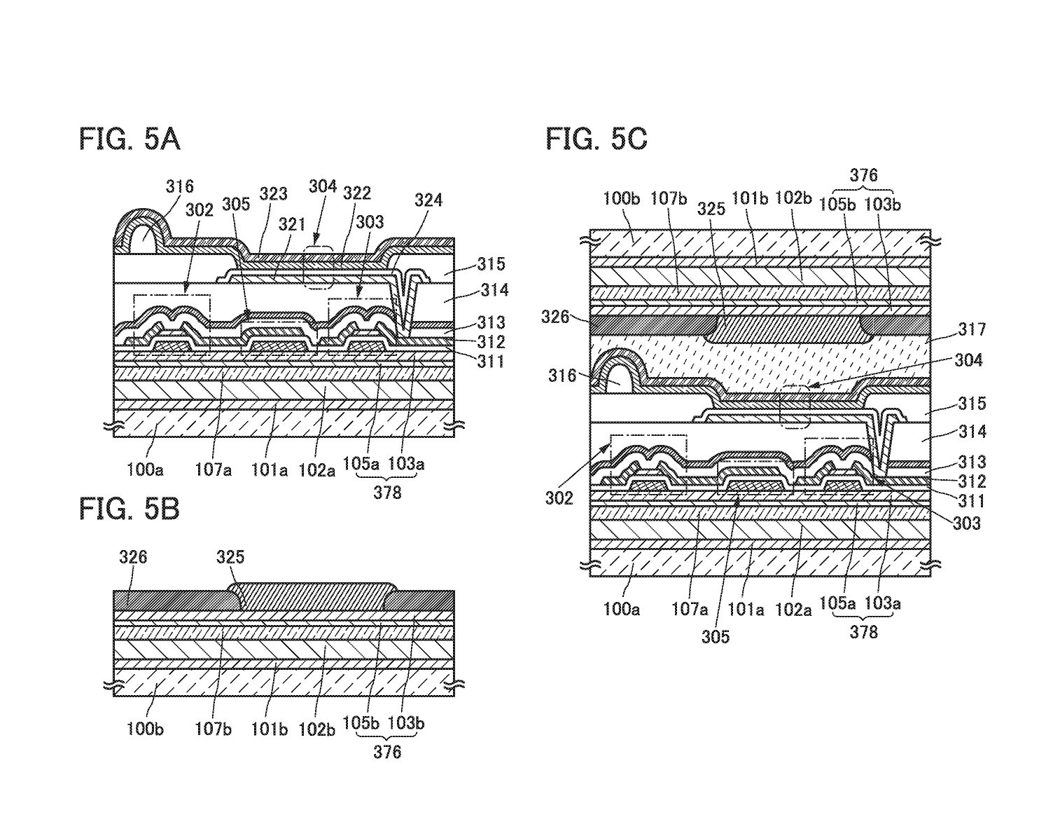

An example of a manufacturing method of the structure example 1 is described with reference to FIGS. 5A to 5C, FIGS. 6A and 6B, and FIGS. 7A and 7B. FIGS. 5A to 5C, FIGS. 6A and 6B, and FIGS. 7A and 7B are cross-sectional views illustrating a method for manufacturing the light-emitting unit 381 of the light-emitting device 370.

First, as shown in FIG. 5A, a first insulating layer 101a is formed over a formation substrate 100a, a second insulating layer 102a is formed over the first insulating layer 101a, and a peeling layer 107a is formed over the second insulating layer 102a. Next, plasma treatment is performed on a surface of the peeling layer 107a, followed by formation of a layer to be peeled over the peeling layer 107a. Here, the layer to be peeled that is formed over the peeling layer 107a corresponds to the layers from the insulating layer 378 to the light-emitting element 304 in FIG. 4. In the example illustrated in FIG. 5A, an insulating layer 105a is formed by the plasma treatment.

A third insulating layer 103a is formed over the insulating layer 105a, whereby the insulating layer 378 can be formed. The insulating layer 378 may further include an insulating layer over the third insulating layer 103a.

After the formation of the insulating layer 378, heat treatment is performed. Then, the other layers of the layer to be peeled are formed. The heat treatment may be performed at any timing as long as it is between the formation of the third insulating layer 103a and peeling. For example, heat treatment performed in the manufacturing process of a transistor may double as the above heat treatment.

As shown in FIG. 5B, a first insulating layer 101b is formed over a formation substrate 100b, a second insulating layer 102b is formed over the first insulating layer 101b, and a peeling layer 107b is formed over the second insulating layer 102b. Next, plasma treatment is performed on a surface of the peeling layer 107b, followed by formation of a layer to be peeled over the peeling layer 107b. Here, the layer to be peeled that is formed over the peeling layer 107b corresponds to the insulating layer 376, the coloring layer 325, and the light-blocking layer 326 in FIG. 4. In the example illustrated in FIG. 5B, an insulating layer 105b is formed by the plasma treatment.

A third insulating layer 103b is formed over the insulating layer 105b, whereby the insulating layer 376 can be formed. The insulating layer 376 may further include an insulating layer over the third insulating layer 103b.

After the formation of the insulating layer 376, heat treatment is performed. Then, the other layers of the layer to be peeled are formed. The heat treatment may be performed at any timing as long as it is between the formation of the third insulating layer 103b and peeling.

The formation substrate 100a and the formation substrate 100b can each be formed using a material similar to that used for the formation substrate 100 described in Embodiment 1.

The first insulating layer 101a and the first insulating layer 101b can each be formed using a material and a film formation method similar to those used for the first insulating layer 101 described in Embodiment 1.

The second insulating layer 102a and the second insulating layer 102b can each be formed using a material and a film formation method similar to those used for the second insulating layer 102 described in Embodiment 1.

The peeling layer 107a and the peeling layer 107b can each be formed using a material and a film formation method similar to those used for the peeling layer 107 described in Embodiment 1.

The third insulating layer 103a and the third insulating layer 103b can each be formed using a material and a film formation method similar to those used for the third insulating layer 103 described in Embodiment 1.

Then, as illustrated in FIG. 5C, the formation substrate 100a and the formation substrate 100b are bonded to each other with the bonding layer 317.

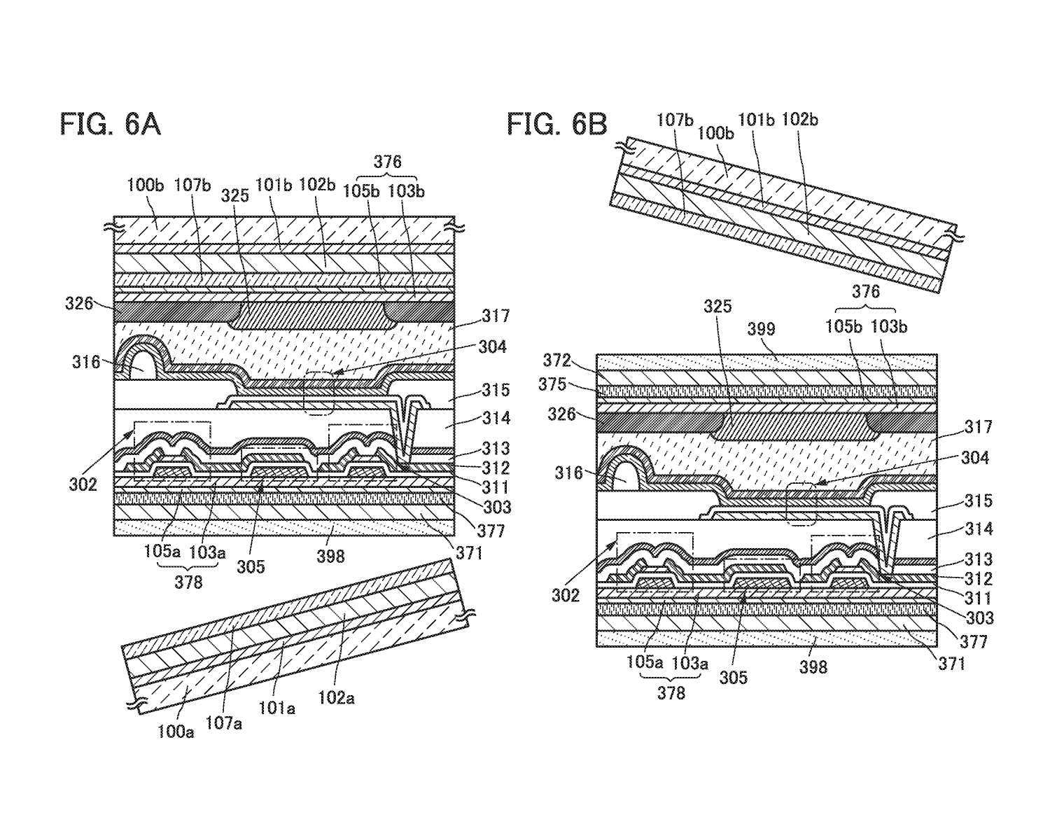

Then, as illustrated in FIG. 6A, the formation substrate 100a and the insulating layer 378 are separated from each other. Note that either of the formation substrate 100a and the formation substrate 100b may be separated first.

Before the separation of the formation substrate 100a and the insulating layer 378, a peeling trigger is preferably formed using laser light, a sharp knife, or the like. The insulating layer 378 is partly cracked (or broken), whereby the peeling trigger can be formed. For example, laser light irradiation enables part of the insulating layer 378 to be melted, evaporated, or thermally broken.

Then, the insulating layer 378 and the formation substrate 100a are separated from the formed peeling trigger by application of physical force. In the lower part of FIG. 6A, the formation substrate 100a, the first insulating layer 101a, the second insulating layer 102a, and the peeling layer 107a that are separated from the insulating layer 378 are illustrated. After that, as illustrated in FIG. 6A, the exposed insulating layer 378 and the substrate 371 are bonded to each other with the bonding layer 377.

In many cases, both sides of a film that can be favorably used as the substrate 371 are provided with peeling films (also referred to as separate films or release films). When the substrate 371 and the insulating layer 378 are bonded to each other, it is preferable that only one of the peeling films which is provided over the substrate 371 be peeled, and the other thereof remain. This facilitates transfer and processing in later steps. FIG. 6A illustrates an example in which one surface of the substrate 371 is provided with a peeling film 398.

Then, as illustrated in FIG. 6B, the formation substrate 100b and the insulating layer 376 are separated from each other. In the upper part of FIG. 6B, the formation substrate 100b, the first insulating layer 101b, the second insulating layer 102b, and the peeling layer 107b that are separated from the insulating layer 376 are illustrated. Next, the exposed insulating layer 376 and the substrate 372 are bonded to each other with the bonding layer 375. FIG. 6B illustrates an example in which one surface of the substrate 372 is provided with a peeling film 399.

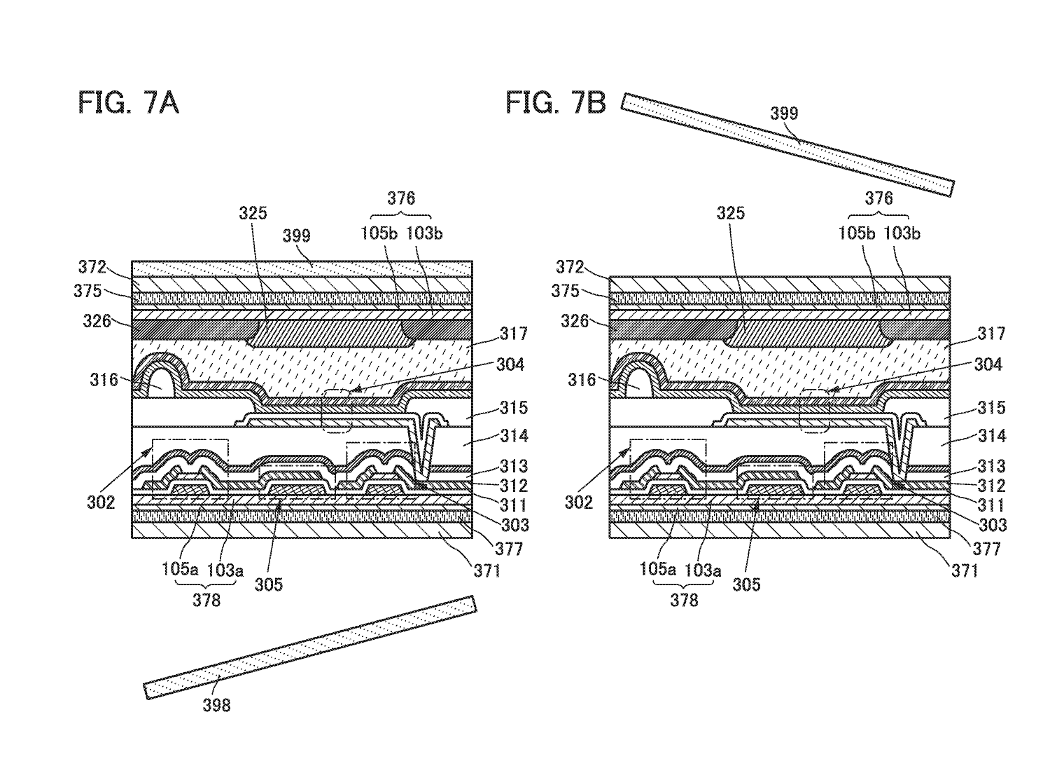

Next, as illustrated in FIG. 7A, the peeling film 398 is peeled. Then, as illustrated in FIG. 7B, the peeling film 399 is peeled. There is no limitation on the order of peeling the peeling films 398 and 399.

As described above, in one embodiment of the present invention, each of the functional elements and the like included in the light-emitting device is formed over the formation substrate; thus, even in the case where a high-resolution light-emitting device is manufactured, high alignment accuracy of the flexible substrate is not required. It is thus easy to attach the flexible substrate. In addition, since the functional element and the like can be fabricated with high temperatures, a highly reliable light-emitting device can be obtained.

By using the peeling method of one embodiment of the present invention, the insulating layer 376 and the insulating layer 378 can be thin. Accordingly, a light-emitting device can be thin and thus can be bent repeatedly with an extremely small radius of curvature. For example, the light-emitting device that can be bent with a radius of curvature of greater than or equal to 0.01 mm and less than or equal to 150 mm can be manufactured. The light-emitting device that can be bent 100000 times with a radius of curvature of 5 mm can be manufactured. The light-emitting device that can be bent 100000 times with a radius of curvature of 2 mm can be manufactured.

### Structure Example 2

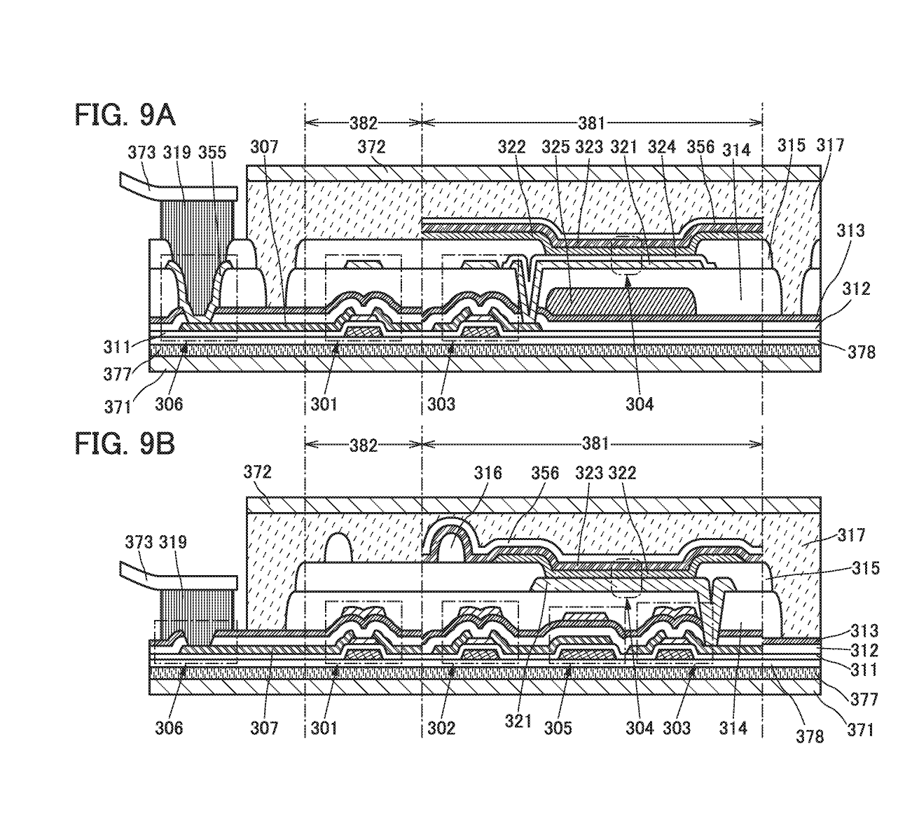

FIG. 9A shows a cross-sectional view of a light-emitting device employing a color filter method. Note that in the following structure examples, components similar to those in the above structure example will not be described in detail.

The light-emitting device in FIG. 9A includes the substrate 371, the bonding layer 377, the insulating layer 378, a plurality of transistors, the conductive layer 307, the insulating layer 312, the insulating layer 313, the insulating layer 314, the insulating layer 315, the light-emitting element 304, the conductive layer 355, the bonding layer 317, the coloring layer 325, the substrate 372, and an insulating layer 356.

The driver circuit unit 382 includes the transistor 301. The light-emitting unit 381 includes the transistor 303.

Each transistor includes two gates, the gate insulating layer 311, a semiconductor layer, a source, and a drain. The two gates each overlap with the semiconductor layer with the insulating layer provided therebetween. FIG. 9A illustrates an example where each transistor has a structure in which the semiconductor layer is sandwiched between the two gates. Such transistors can have higher field-effect mobility and thus have higher on-state current than other transistors. Consequently, a circuit capable of high-speed operation can be obtained. Furthermore, the area occupied by a circuit can be reduced. The use of the transistor having high on-state current can reduce signal delay in wirings and can reduce display luminance variation even in a light-emitting device in which the number of wirings is increased because of an increase in size or resolution. FIG. 9A illustrates an example in which one of the gates is formed using the same material and the same step as the electrode 321.

The light-emitting element 304 has a bottom-emission structure with which light is emitted to the coloring layer 325 side.

The light-emitting element 304 overlaps with the coloring layer 325 with the insulating layer 314 provided therebetween. The coloring layer 325 is provided between the light-emitting element 304 and the substrate 371. FIG. 9A illustrates an example in which the coloring layer 325 is provided over the insulating layer 313. In the example illustrated in FIG. 9A, a light-blocking layer and a spacer are not provided.

The insulating layer 356 serves as a sealing layer for the light-emitting element 304. The insulating layer 356 preferably contains nitrogen and silicon. The insulating layer 356 can be formed using a silicon nitride film, a silicon oxynitride film, or a silicon nitride oxide film, for example. In particular, a silicon nitride film or a silicon nitride oxide film is preferably used. An aluminum oxide film can also be used as the insulating layer 356. The aluminum oxide film is preferably formed by an ALD method.

### Structure Example 3

FIG. 9B shows a cross-sectional view of a light-emitting device employing a separate coloring method.

The light-emitting device in FIG. 9B includes the substrate 371, the bonding layer 377, the insulating layer 378, a plurality of transistors, the conductive layer 307, the insulating layer 312, the insulating layer 313, the insulating layer 314, the insulating layer 315, the spacer 316, the light-emitting element 304, the bonding layer 317, the substrate 372, and the insulating layer 356.

The driver circuit unit 382 includes the transistor 301. The light-emitting unit 381 includes the transistor 302, the transistor 303, and the capacitor 305.

Each transistor includes two gates, the gate insulating layer 311, a semiconductor layer, a source, and a drain. The two gates each overlap with the semiconductor layer with the insulating layer provided therebetween. FIG. 9B illustrates an example where each transistor has a structure in which the semiconductor layer is sandwiched between the two gates. In the example illustrated in FIG. 9B, one of the gates is formed between the insulating layer 313 and the insulating layer 314.

The light-emitting element 304 has a top-emission structure in which light is emitted to the substrate 372 side. In the example illustrated in FIG. 9B, the light-emitting element 304 does not include an optical adjustment layer. The insulating layer 356 functions as a sealing layer for the light-emitting element 304.

The connection portion 306 includes the conductive layer 307. The conductive layer 307 is electrically connected to the FPC 373 through the connector 319.

### Application Example

In one embodiment of the present invention, a display device provided with a touch sensor (hereinafter also referred to as a touch panel) can be manufactured.

There is no particular limitation on a sensor element included in the touch panel of one embodiment of the present invention. Note that a variety of sensors that can sense proximity or touch of a sensing target such as a finger or a stylus can be used as the sensor element.

For example, a variety of types such as a capacitive type, a resistive type, a surface acoustic wave type, an infrared type, an optical type, and a pressure-sensitive type can be used for the sensor.

In this embodiment, a touch panel including a capacitive sensor element is described as an example.

Examples of the capacitive sensor element include a surface capacitive sensor element and a projected capacitive sensor element. Examples of the projected capacitive sensor element include a self-capacitive sensor element and a mutual capacitive sensor element. The use of a mutual capacitive sensor element is preferable because multiple points can be sensed simultaneously.

The touch panel of one embodiment of the present invention can have any of a variety of structures, including a structure in which a light-emitting device or a display device and a sensor element that are separately formed are bonded to each other and a structure in which an electrode and the like included in a sensor element are provided on one or both of a substrate supporting a light-emitting element and a counter substrate.

### Structure Example 4

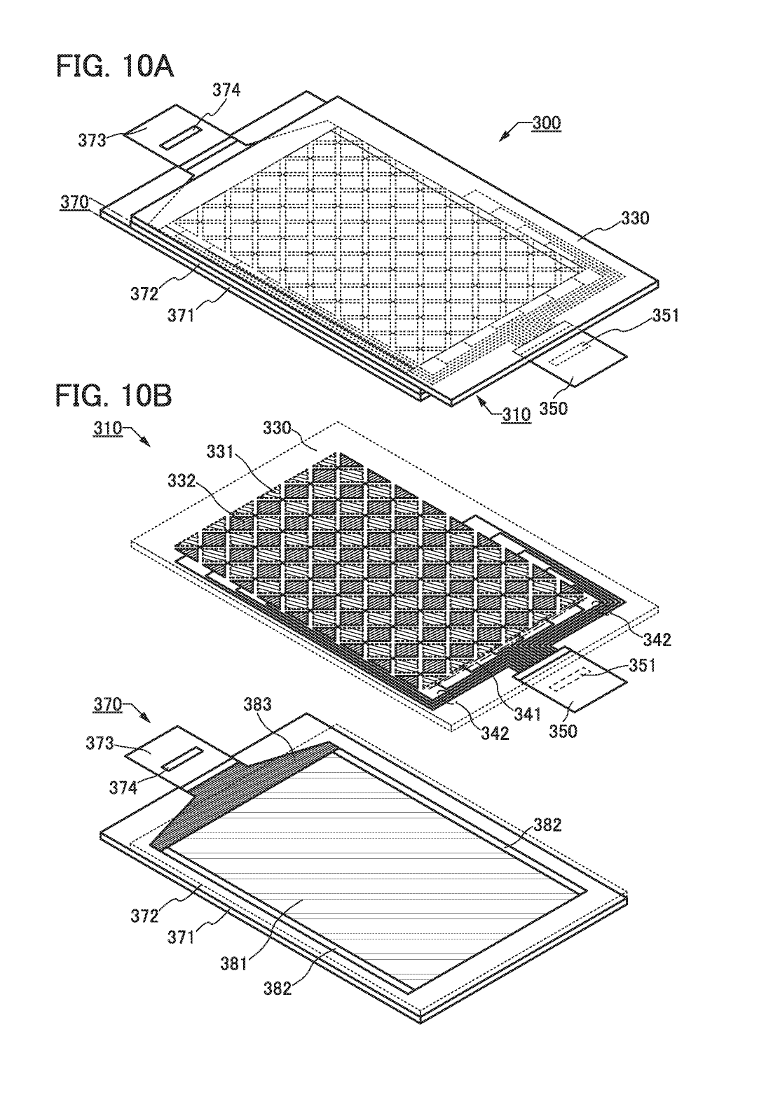

FIG. 10A is a schematic perspective view of a touch panel 300. FIG. 10B is a developed view of the schematic perspective view of FIG. 10A. Note that only typical components are illustrated for simplicity. In FIG. 10B, some components (such as the substrate 330 and the substrate 372) are illustrated only in dashed outline.

The touch panel 300 includes an input device 310 and the light-emitting device 370, which are provided to overlap with each other.

The input device 310 includes the substrate 330, an electrode 331, an electrode 332, a plurality of wirings 341, and a plurality of wirings 342. An FPC 350 is electrically connected to each of the plurality of wirings 341 and the plurality of wirings 342. The FPC 350 is provided with an IC 351.

The light-emitting device 370 includes the substrate 371 and the substrate 372 which are provided so as to face each other. The light-emitting device 370 includes the light-emitting unit 381 and the driver circuit unit 382. A wiring 383 and the like are provided over the substrate 371. The FPC 373 is electrically connected to the wiring 383. The FPC 373 is provided with an IC 374.

The wiring 383 has a function of supplying a signal and power to the light-emitting unit 381 and the driver circuit unit 382. The signal and power are each input to the wiring 383 from the outside or the IC 374 through the FPC 373.

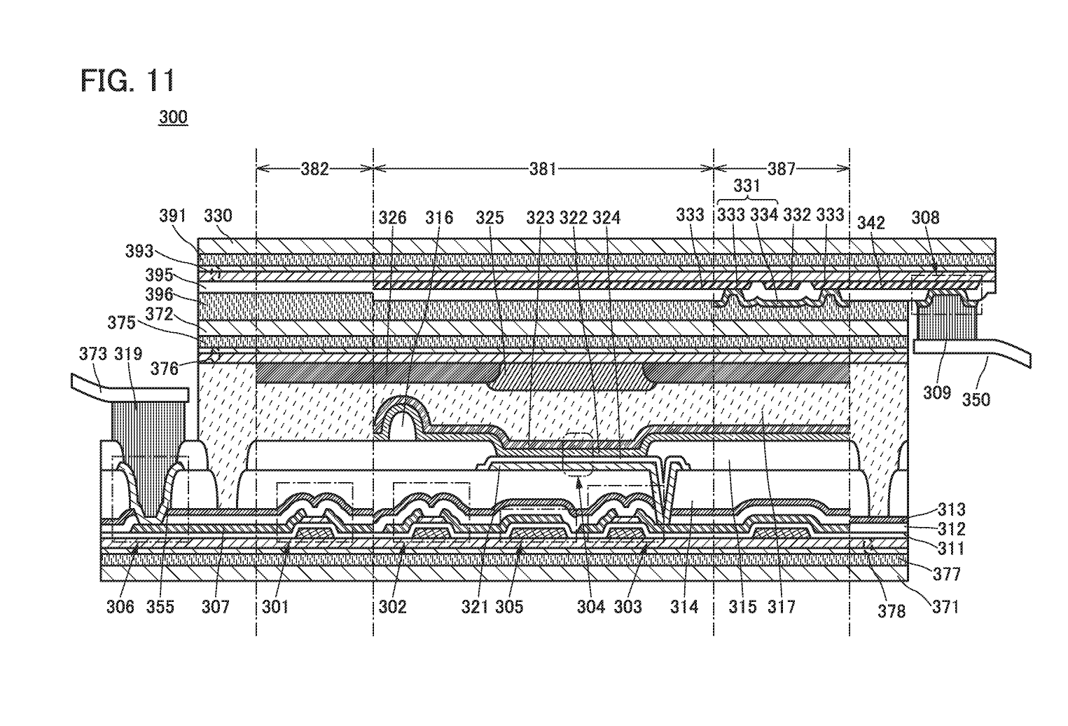

FIG. 11 illustrates an example of a cross-sectional view of the touch panel 300. FIG. 11 shows cross-sectional structures of the light-emitting unit 381, the driver circuit unit 382, the region including the FPC 373, the region including the FPC 350, and the like. Furthermore, FIG. 11 illustrates a cross-sectional structure of a crossing portion 387 where a wiring formed by processing a conductive layer used for forming the gate of the transistor and a wiring formed by processing a conductive layer used for forming the source and the drain of the transistor cross each other.

The substrate 371 and the substrate 372 are bonded to each other with the bonding layer 317. The substrate 372 and the substrate 330 are bonded to each other with a bonding layer 396. Here, the layers from the substrate 371 to the substrate 372 correspond to the light-emitting device 370. Furthermore, the layers from the substrate 330 to the electrode 334 correspond to the input device 310. In other words, the bonding layer 396 bonds the light-emitting device 370 and the input device 310 together. Alternatively, the layers from the substrate 371 to the insulating layer 376 correspond to the light-emitting device 370. Furthermore, the layers from the substrate 330 to the substrate 372 correspond to the input device 310. In other words, the bonding layer 375 bonds the light-emitting device 370 and the input device 310 together.

The structure of the light-emitting device 370 shown in FIG. 11 is similar to that of the light-emitting device shown in FIG. 4 and is thus not described in detail.

### <Input Device 310>

On the substrate 372 side of the substrate 330, the electrode 331 and the electrode 332 are provided. An example where the electrode 331 includes an electrode 333 and the electrode 334 is described here. As illustrated in the crossing portion 387 in FIG. 11, the electrodes 332 and 333 are formed on the same plane. An insulating layer 395 is provided to cover the electrode 332 and the electrode 333. The electrode 334 electrically connects two electrodes 333, between which the electrode 332 is provided, through openings formed in the insulating layer 395.

In a region near the end portion of the substrate 330, a connection portion 308 is provided. The connection portion 308 has a stack of the wiring 342 and a conductive layer formed by processing a conductive layer used for forming the electrode 334. The connection portion 308 is electrically connected to the FPC 350 through a connector 309.

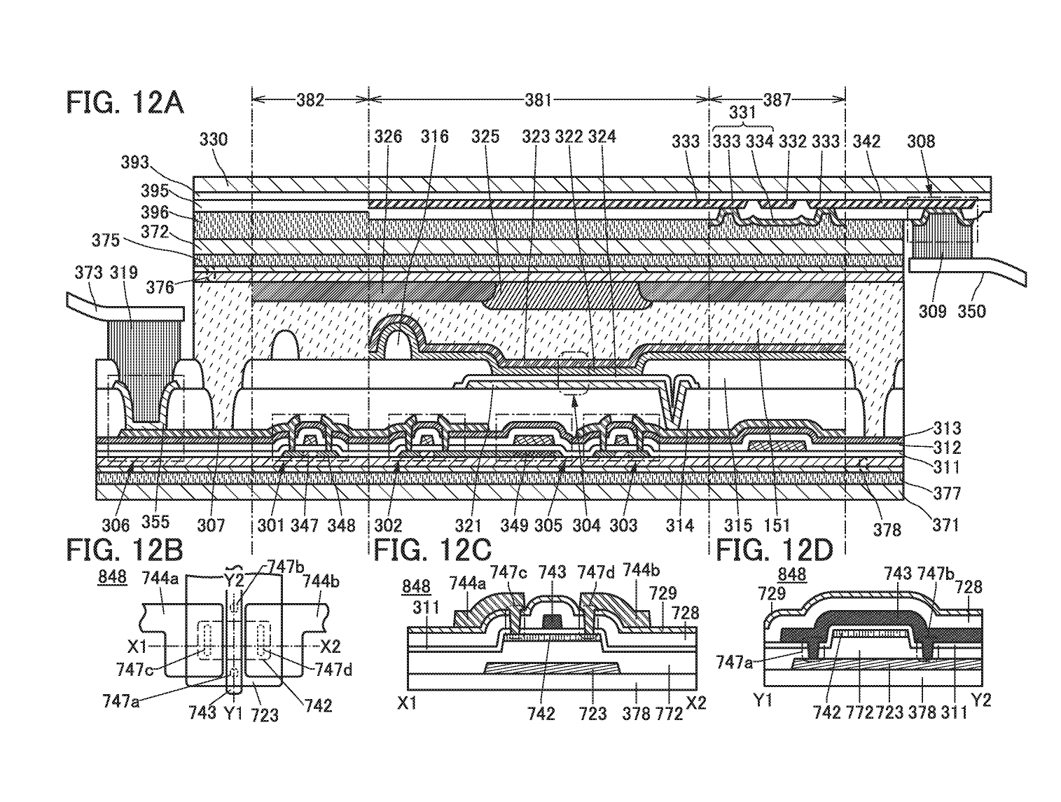

The substrate 330 is bonded to an insulating layer 393 with a bonding layer 391. As in the manufacturing method for the structure example 1, the input device 310 can also be manufactured by forming elements over a formation substrate, peeling the formation substrate, and then transferring the elements over the substrate 330. In the example illustrated in FIG. 11, the insulating layer 393 has a two-layer structure. Of the two layers included in the insulating layer 393, the layer on the bonding layer 391 side corresponds to the insulating layer in Embodiment 1 that is formed during the plasma treatment, and the layer on the insulating layer 395 side corresponds to the third insulating layer 103 described in Embodiment 1. Alternatively, the insulating layer 393, the elements, and the like may be directly formed on the substrate 330 (see FIG. 12A).

### Structure Example 5

The touch panel shown in FIG. 12A is different from the touch panel in FIG. 11 in the structures of the transistors 301, 302, and 303 and the capacitor 305 and in not including the bonding layer 391.

FIG. 12A illustrates an example of using top-gate transistors.

Each transistor includes a gate, the gate insulating layer 311, a semiconductor layer, a source, and a drain. The gate and the semiconductor layer overlap with each other with the gate insulating layer 311 provided therebetween. The semiconductor layer may include low-resistance regions 348. The low-resistance regions 348 function as the source and drain of the transistor.

The conductive layer over the insulating layer 313 functions as a lead wiring. The conductive layer is electrically connected to the region 348 via an opening provided in the insulating layer 313, the insulating layer 312, and the gate insulating layer 311.

In FIG. 12A, the capacitor 305 has a stacked-layer structure that includes a layer formed by processing a semiconductor layer used for forming the above-described semiconductor layer, the gate insulating layer 311, and a layer formed by processing a conductive layer used for forming the gate. Here, part of the semiconductor layer of the capacitor 305 preferably has a region 349 having a higher conductivity than a region 347 where the channel of the transistor is formed.

The region 348 and the region 349 each can be a region containing more impurities than the region 347 where the channel of the transistor is formed, a region having a higher carrier concentration than the region 347, a region having lower crystallinity than the region 347, or the like.

A transistor 848 illustrated in FIGS. 12B to 12D can be used in the light-emitting device of one embodiment of the present invention.

FIG. 12B is a top view of the transistor 848. FIG. 12C is a cross-sectional view in the channel length direction of the transistor 848 in the light-emitting device of one embodiment of the present invention. The cross section of the transistor 848 illustrated in FIG. 12C is taken along the dashed-dotted line X1-X2 in FIG. 12B. FIG. 12D is a cross-sectional view in the channel width direction of the transistor 848 in the light-emitting device of one embodiment of the present invention. The cross section of the transistor 848 illustrated in FIG. 12D is taken along the dashed-dotted line Y1-Y2 in FIG. 12B.

The transistor 848 is a type of top-gate transistor including a back gate.

In the transistor 848, a semiconductor layer 742 is formed over a projection of an insulating layer 772. When the semiconductor layer 742 is provided over the projection of the insulating layer 772, the side surface of the semiconductor layer 742 can also be covered with a gate 743. Thus, the transistor 848 has a structure in which the semiconductor layer 742 can be electrically surrounded by an electric field of the gate 743. Such a structure of a transistor in which a semiconductor film in which a channel is formed is electrically surrounded by an electric field of a conductive film is called a surrounded channel (s-channel) structure. A transistor with an s-channel structure is referred to as an s-channel transistor.

In the s-channel structure, a channel can be formed in the whole (bulk) of the semiconductor layer 742. In the s-channel structure, the drain current of the transistor can be increased, so that a larger amount of on-state current can be obtained. Furthermore, the entire channel formation region of the semiconductor layer 742 can be depleted by the electric field of the gate 743. Accordingly, the off-state current of the transistor with the s-channel structure can further be reduced.

A back gate 723 is provided over the insulating layer 378.

A conductive layer 744a provided over an insulating layer 729 is electrically connected to the semiconductor layer 742 through an opening 747c formed in the gate insulating layer 311, an insulating layer 728, and the insulating layer 729. A conductive layer 744b provided over the insulating layer 729 is electrically connected to the semiconductor layer 742 through an opening 747d formed in the gate insulating layer 311 and the insulating layers 728 and 729.

The gate 743 provided over the gate insulating layer 311 is electrically connected to the back gate 723 through an opening 747a and an opening 747b formed in the gate insulating layer 311 and the insulating layer 772. Accordingly, the same potential is supplied to the gate 743 and the back gate 723. Furthermore, either or both of the openings 747a and 747b may be omitted. In the case where both the openings 747a and 747b are omitted, different potentials can be supplied to the back gate 723 and the gate 743.

As a semiconductor in the transistor having the s-channel structure, an oxide semiconductor, silicon such as polycrystalline silicon or single crystal silicon that is transferred from a single crystal silicon substrate, or the like is used.

### Structure Example 6

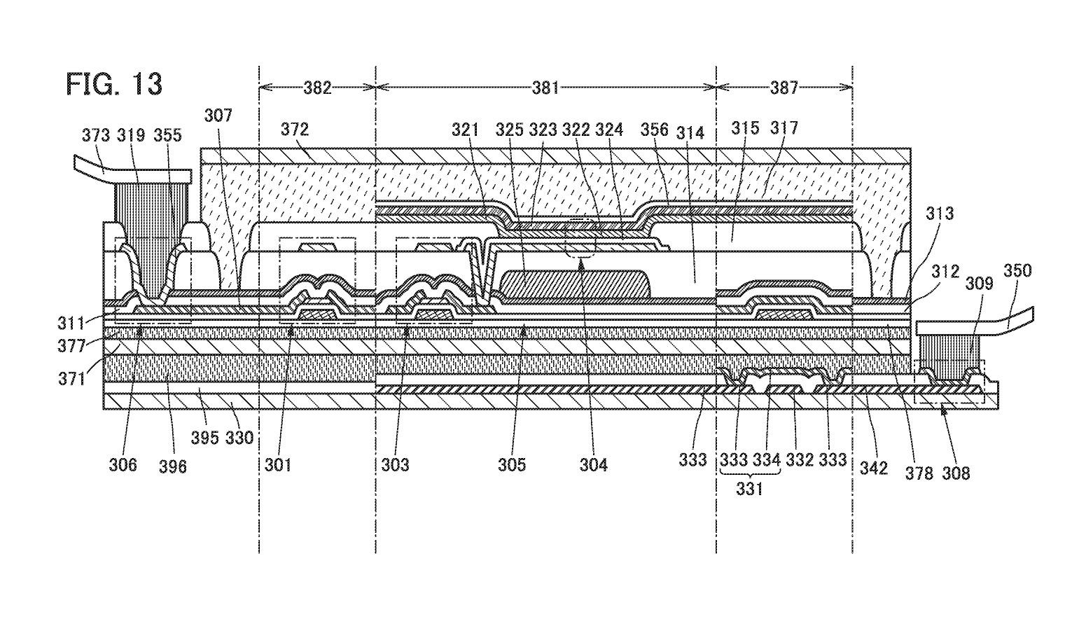

FIG. 13 shows an example of a touch panel in which a bottom-emission light-emitting device and an input device are bonded to each other with the bonding layer 396.

The light-emitting device illustrated in FIG. 13 has a structure similar to that illustrated in FIG. 9A. The input device in FIG. 13 is different from that in FIG. 12A in that the insulating layer 393 is not provided and that the electrode 331, the electrode 332, and the like are provided directly on the substrate 330.

### Structure Example 7

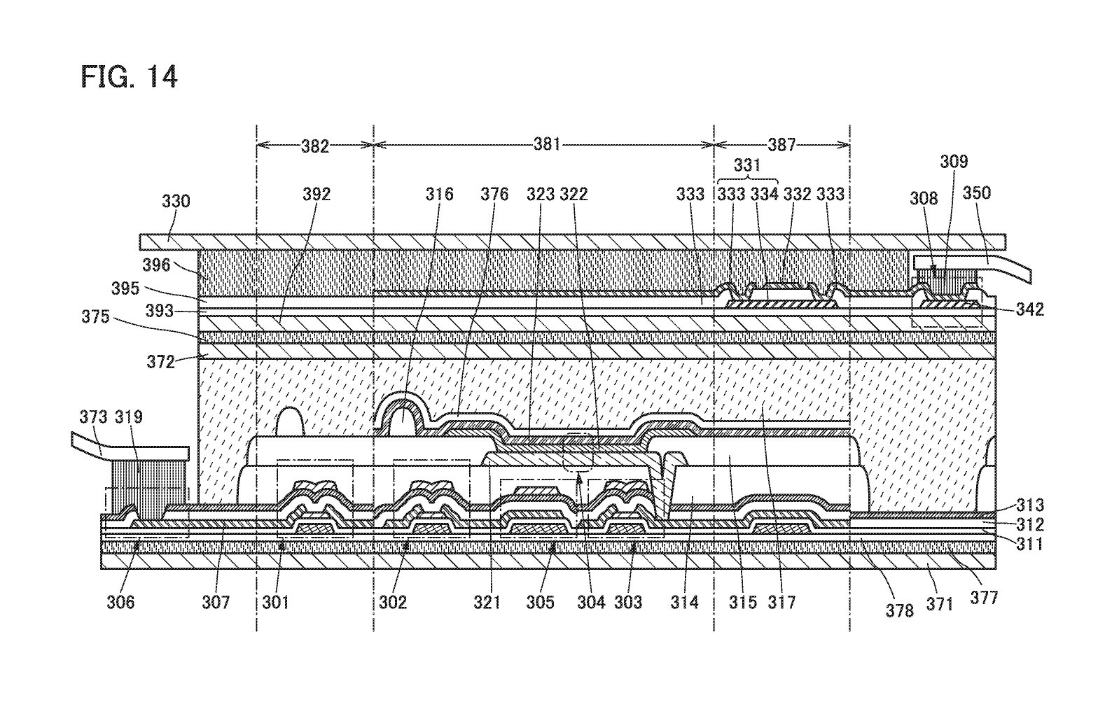

FIG. 14 shows an example of a touch panel in which a light-emitting device using a separate coloring method and an input device are bonded to each other with the bonding layer 375.

The light-emitting device in FIG. 14 has a structure similar to that in FIG. 9B.

The input device in FIG. 14 includes the insulating layer 393 over a substrate 392, and the electrode 334 and the wiring 342 over the insulating layer 393. The electrode 334 and the wiring 342 are covered with the insulating layer 395. The electrode 332 and the electrode 333 are provided over the insulating layer 395. The substrate 330 is bonded to the substrate 392 with the bonding layer 396.

### Structure Example 8

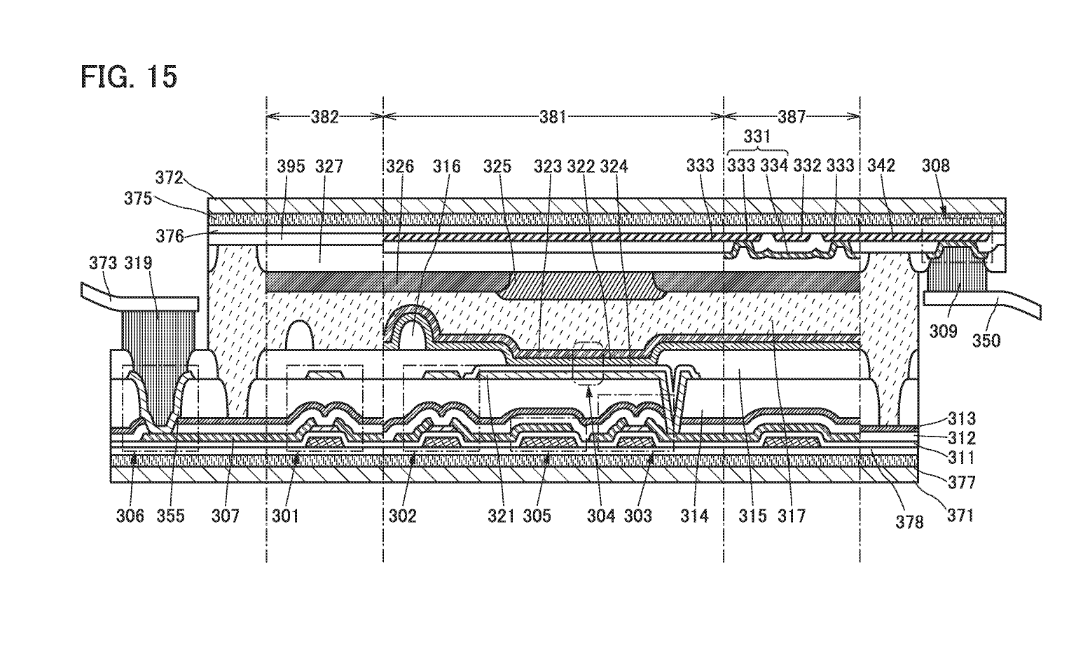

FIG. 15 shows an example in which a touch sensor and the light-emitting element 304 are provided between a pair of flexible substrates (the substrate 371 and the substrate 372). When two flexible substrates are used, the touch panel can be thin, lightweight, and flexible.

The structure in FIG. 15 can be fabricated by changing the structure of the layer to be peeled that is formed over the formation substrate 100b in the manufacturing process example for the structure example 1. In the manufacturing process example for the structure example 1, as the layer to be peeled that is formed over the formation substrate 100b, the insulating layer 376, the coloring layer 325, and the light-blocking layer 326 are formed (FIG. 5B).

In the case where the structure in FIG. 15 is fabricated, after the insulating layer 376 is formed, the electrode 332, the electrode 333, and the wiring 342 are formed over the insulating layer 376. Then, the insulating layer 395 covering these electrodes is formed. Next, the electrode 334 is formed over the insulating layer 395. Then, an insulating layer 327 covering the electrode 334 is formed. After that, the coloring layer 325 and the light-blocking layer 326 are formed over the insulating layer 327. Then, the formation substrate 100b is bonded to the formation substrate 100a, the formation substrates are peeled, and the flexible substrates are bonded; thus, the touch panel having the structure in FIG. 15 can be fabricated.

### Structure Example 9

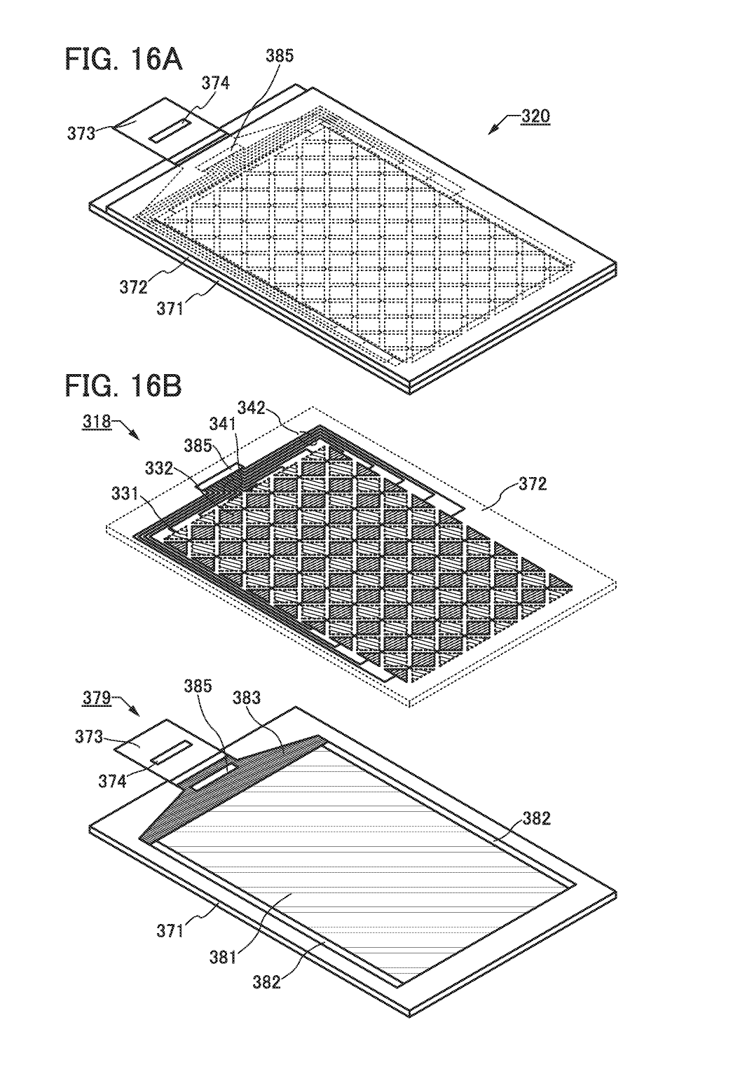

FIGS. 16A and 16B are schematic perspective views of a touch panel 320.

In FIGS. 16A and 16B, the substrate 372 is provided with an input device 318. The wiring 341, the wiring 342, and the like of the input device 318 are electrically connected to the FPC 373 provided for a light-emitting device 379.

With the above structure, the FPC connected to the touch panel 320 can be provided only on one substrate side (on the substrate 371 side in this embodiment). Although two or more FPCs may be attached to the touch panel 320, it is preferable that the touch panel 320 be provided with one FPC 373 which has a function of supplying signals to both the light-emitting device 379 and the input device 318 as illustrated in FIGS. 16A and 16B, for the simplicity of the structure.

The IC 374 can have a function of driving the input device 318. Alternatively, an IC for driving the input device 318 may further be provided. Further alternatively, an IC for driving the input device 318 may be mounted on the substrate 371.

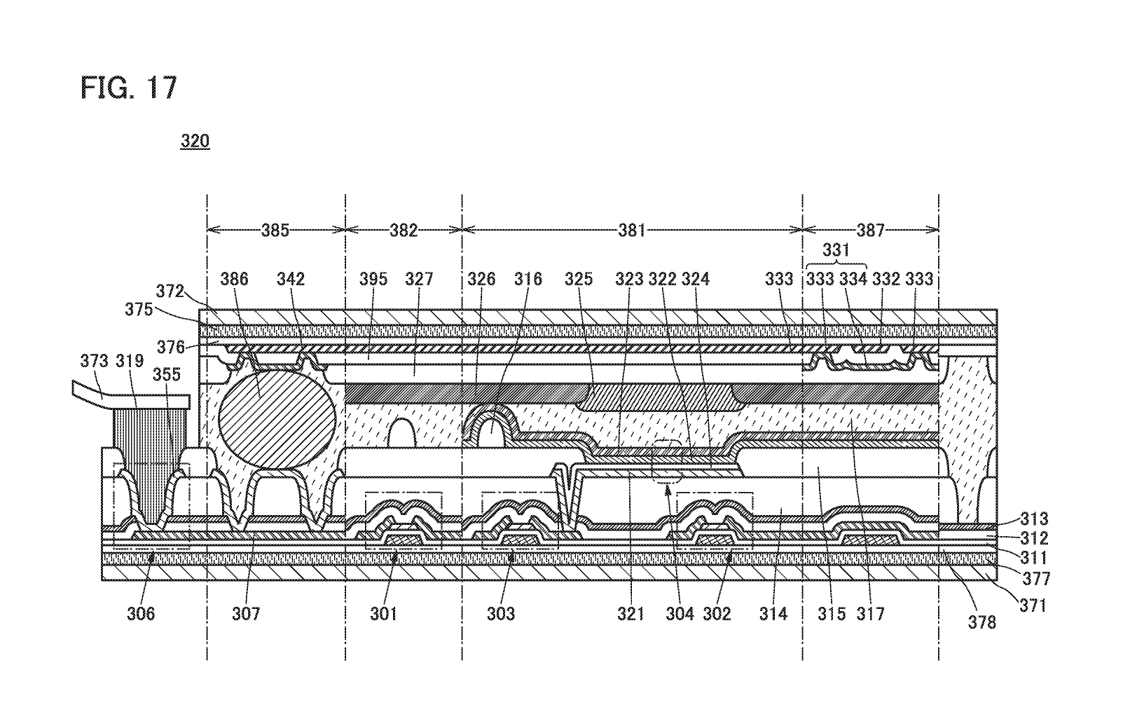

FIG. 17 is a cross-sectional view showing a region including the FPC 373, a connection portion 385, the driver circuit unit 382, and the light-emitting unit 381 in FIGS. 16A and 16B.

In the connection portion 385, one of the wirings 342 (or the wirings 341) and one of the conductive layers 307 are electrically connected to each other via a connector 386.

As the connector 386, a conductive particle can be used, for example. As the conductive particle, a particle of an organic resin, silica, or the like coated with a metal material can be used. It is preferable to use nickel or gold as the metal material because contact resistance can be decreased. It is also preferable to use a particle coated with layers of two or more kinds of metal materials, such as a particle coated with nickel and further with gold. As the connector 386, a material capable of elastic deformation or plastic deformation is preferably used. As illustrated in FIG. 17, the conductive particle has a shape that is vertically crushed in some cases. With the crushed shape, the contact area between the connector 386 and a conductive layer electrically connected to the connector 386 can be increased, thereby reducing contact resistance and suppressing the generation of problems such as disconnection.

The connector 386 is preferably provided so as to be covered with the bonding layer 317. For example, the connector 386 is dispersed in the bonding layer 317 before curing of the bonding layer 317. A structure in which the connection portion 385 is provided in a portion where the bonding layer 317 is provided can be similarly applied not only to a structure in which the bonding layer 317 is also provided over the light-emitting element 304 as illustrated in FIG. 17 (also referred to as a solid sealing structure) but also to, for example, a hollow sealing structure in which the bonding layer 317 is provided in the periphery of a light-emitting device, a liquid crystal display device, or the like.

FIG. 17 illustrates an example in which the optical adjustment layer 324 does not cover an end portion of the electrode 321. In the example in FIG. 17, the spacer 316 is also provided in the driver circuit unit 382.

### Structural Example 10

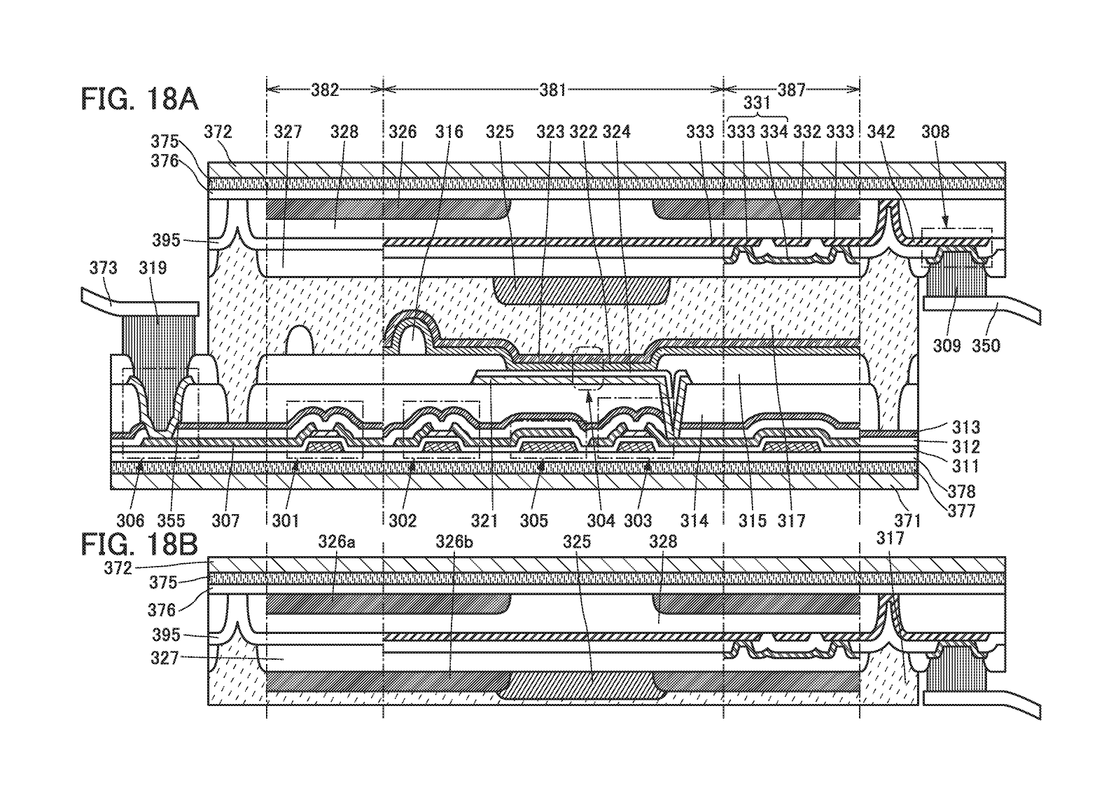

In a touch panel illustrated in FIG. 18A, the light-blocking layer 326 is provided between the electrodes and the like of the touch sensor and the substrate 372. Specifically, the light-blocking layer 326 is provided between the insulating layer 376 and an insulating layer 328. Conductive layers including the electrodes 332 and 333 and the wirings 342, the insulating layer 395 covering these conductive layers, the electrode 334 over the insulating layer 395, and the like are provided over the insulating layer 328. Furthermore, the insulating layer 327 is provided over the electrode 334 and the insulating layer 395, and the coloring layer 325 is provided over the insulating layer 327.

The insulating layers 327 and 328 each function as a planarization film. Note that the insulating layers 327 and 328 are not necessarily provided when not needed.

With such a structure, the light-blocking layer 326 provided in a position closer to the substrate 372 side than the electrodes and the like of the touch sensor can prevent the electrodes and the like from being seen by a user. Thus, a touch panel with not only a small thickness but also improved display quality can be achieved.

As illustrated in FIG. 18B, the touch panel may include a light-blocking layer 326a between the insulating layer 376 and the insulating layer 328 and may include a light-blocking layer 326b between the insulating layer 327 and the bonding layer 317. Providing the light-blocking layer 326b can inhibit light leakage more surely.

As described above, with the use of the peeling method of one embodiment of the present invention, a thin and repeatedly bendable light-emitting device can be manufactured. In addition, a thin light-emitting device that can be bent with an extremely small radius of curvature can be manufactured.

This embodiment can be combined with any other embodiment as appropriate.

### Embodiment 3

In this embodiment, electronic devices and lighting devices of embodiments of the present invention will be described with reference to drawings.

The use of the peeling method of one embodiment of the present invention makes it possible to manufacture a light-emitting device, a display device, a semiconductor device, or the like that is thin, lightweight, curved, or flexible. The use of such a light-emitting device, a display device, a semiconductor device, or the like using one embodiment of the present invention makes it possible to manufacture an electronic device or a lighting device that is thin, lightweight, curved, or flexible.

Examples of electronic devices are television devices (also referred to as TV or television receivers), monitors for computers and the like, cameras such as digital cameras and digital video cameras, digital photo frames, cellular phones (also referred to as portable telephone devices), portable game machines, portable information terminals, audio playback devices, large game machines such as pin-ball machines, and the like.

The electronic device or the lighting device of one embodiment of the present invention has flexibility and thus can be incorporated along a curved inside/outside wall surface of a house or a building or a curved interior/exterior surface of an automobile.

Furthermore, the electronic device of one embodiment of the present invention may include a secondary battery. It is preferable that the secondary battery be capable of being charged by non-contact power transmission.

Examples of the secondary battery include a lithium ion secondary battery such as a lithium polymer battery using a gel electrolyte (lithium ion polymer battery), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display an image, data, or the like on a display portion. When the electronic device includes the antenna and a secondary battery, the antenna may be used for contactless power transmission.

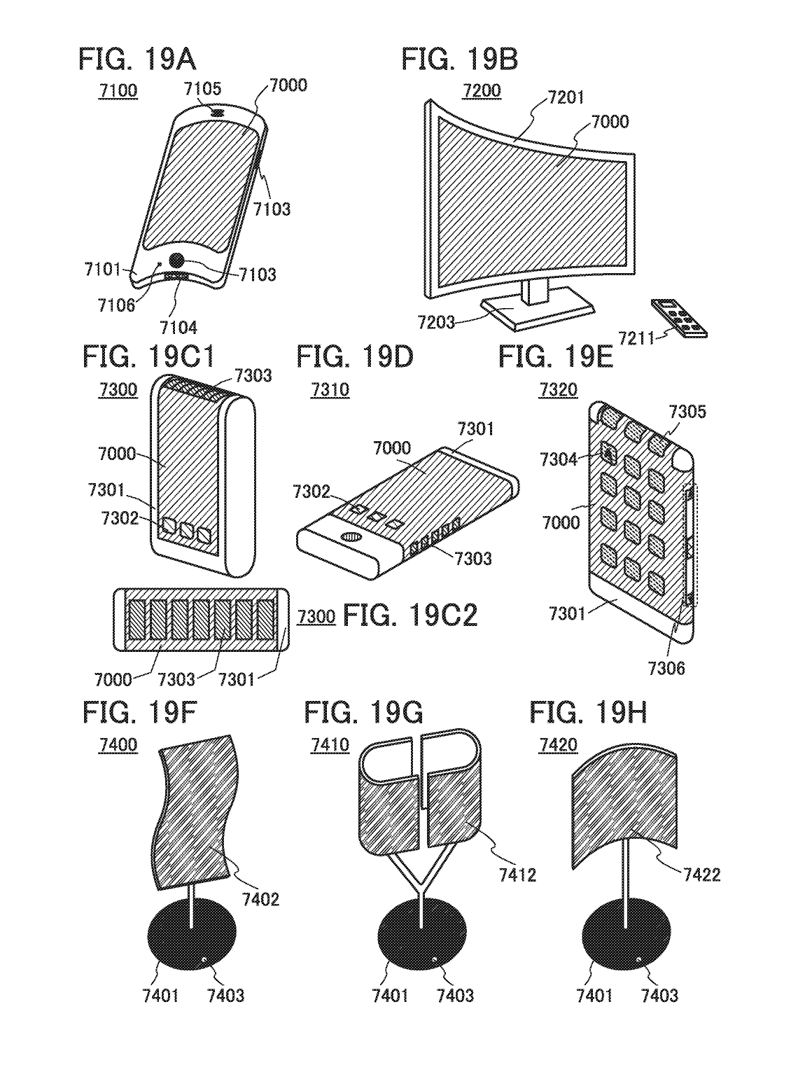

FIGS. 19A, 19B, 19C1, 19C2, 19D, and 19E illustrate examples of electronic devices each including a display portion 7000 with a curved surface. The display surface of the display portion 7000 is curved, and images can be displayed on the curved display surface. Note that the display portion 7000 may be flexible.

The display portion 7000 includes the light-emitting device, display device, or input/output device manufactured using the peeling method of one embodiment of the present invention.

One embodiment of the present invention makes it possible to provide an electronic device having a curved display portion.

FIG. 19A illustrates an example of a cellular phone. A cellular phone 7100 is provided with a housing 7101, the display portion 7000, operation buttons 7103, an external connection port 7104, a speaker 7105, a microphone 7106, and the like.

The cellular phone 7100 illustrated in FIG. 19A includes a touch sensor in the display portion 7000. Moreover, operations such as making a call and inputting a letter can be performed by touch on the display portion 7000 with a finger, a stylus, or the like.

The power can be turned on or off with the operation button 7103. In addition, types of images displayed on the display portion 7000 can be switched; for example, switching images from a mail creation screen to a main menu screen is performed with the operation button 7103.

FIG. 19B illustrates an example of a television set. In a television set 7200, the display portion 7000 is incorporated into a housing 7201. Here, the housing 7201 is supported by a stand 7203.

The television set 7200 illustrated in FIG. 19B can be operated with an operation switch of the housing 7201 or a separate remote controller 7211. Alternatively, the display portion 7000 may include a touch sensor. The display portion 7000 can be operated by touching the display portion with a finger or the like. The remote controller 7211 may be provided with a display portion for displaying data output from the remote controller 7211. With operation keys or a touch panel of the remote controller 7211, channels and volume can be controlled and images displayed on the display portion 7000 can be controlled.

Note that the television set 7200 is provided with a receiver, a modem, or the like. A general television broadcast can be received with the receiver. Furthermore, when the television set is connected to a communication network with or without wires via the modem, one-way (from a transmitter to a receiver) or two-way (between a transmitter and a receiver or between receivers) data communication can be performed.

FIGS. 19C1, 19C2, 19D, and 19E illustrate examples of portable information terminals. Each portable information terminal includes a housing 7301 and the display portion 7000. Each portable information terminal may also include an operation button, an external connection port, a speaker, a microphone, an antenna, a battery, or the like. The display portion 7000 is provided with a touch sensor. An operation of the portable information terminal can be performed by touching the display portion 7000 with a finger, a stylus, or the like.

FIG. 19C1 is a perspective view of a portable information terminal 7300. FIG. 19C2 is a top view of the portable information terminal 7300. FIG. 19D is a perspective view of a portable information terminal 7310. FIG. 19E is a perspective view of a portable information terminal 7320.

Each of the portable information terminals described in this embodiment functions as, for example, one or more of a telephone set, a notebook, and an information browsing system. Specifically, each of the portable information terminals can be used as a smartphone. Each of the portable information terminals illustrated in this embodiment is capable of executing a variety of applications such as mobile phone calls, e-mailing, reading and editing texts, music reproduction, Internet communication, and a computer game, for example.

The portable information terminals 7300, 7310, and 7320 can each display characters, image information, and the like on their plurality of surfaces. For example, as illustrated in FIGS. 19C1 and 19D, three operation buttons 7302 can be displayed on one surface, and information 7303 indicated by a rectangle can be displayed on another surface. FIGS. 19C1 and 19C2 illustrate an example in which information is displayed at the top of the portable information terminal. FIG. 19D illustrates an example in which information is displayed on the side of the portable information terminal. Information may also be displayed on three or more surfaces of the portable information terminal. FIG. 19E illustrates an example where information 7304, information 7305, and information 7306 are displayed on different surfaces.

Examples of the information include notification from a social networking service (SNS), display indicating reception of an e-mail or an incoming call, the subject of an e-mail or the like, the sender of an e-mail or the like, the date, the time, remaining battery level, and the reception strength of an antenna. Alternatively, the operation button, an icon, or the like may be displayed in place of the information.

For example, a user of the portable information terminal 7300 can see the display (here, the information 7303) with the portable information terminal 7300 put in a breast pocket of his/her clothes.

Specifically, a caller's phone number, name, or the like of an incoming call is displayed in a position that can be seen from above the portable information terminal 7300. Thus, the user can see the display without taking out the portable information terminal 7300 from the pocket and decide whether to answer the call.

FIGS. 19F to 19H each illustrate an example of a lighting device having a curved light-emitting portion.

The light-emitting portion included in the lighting device illustrated in each of FIGS. 19F to 19H includes the light-emitting device manufactured using the peeling method of one embodiment of the present invention.

According to one embodiment of the present invention, a lighting device having a curved light-emitting portion can be provided.

A lighting device 7400 illustrated in FIG. 19F includes a light-emitting portion 7402 having a wave-shaped light-emitting surface, which is a good-design lighting device.

A light-emitting portion 7412 included in a lighting device 7410 illustrated in FIG. 19G has two convex-curved light-emitting portions symmetrically placed. Thus, light radiates from the lighting device 7410.

A lighting device 7420 illustrated in FIG. 19H includes a concave-curved light-emitting portion 7422. This is suitable for illuminating a specific range because light emitted from the light-emitting portion 7422 is collected to the front of the lighting device 7420. In addition, with this structure, a shadow is less likely to be produced.

The light-emitting portion included in each of the lighting devices 7400, 7410, and 7420 may be flexible. The light-emitting portion may be fixed on a plastic member, a movable frame, or the like so that an emission surface of the light-emitting portion can be bent freely depending on the intended use.

The lighting devices 7400, 7410, and 7420 each include a stage 7401 provided with an operation switch 7403 and a light-emitting portion supported by the stage 7401.

Note that although the lighting device in which the light-emitting portion is supported by the stage is described as an example here, a housing provided with a light-emitting portion can be fixed on a ceiling or suspended from a ceiling. Since the light-emitting surface can be curved, the light-emitting surface is curved to have a concave shape, whereby a particular area can be brightly illuminated, or the light-emitting surface is curved to have a convex shape, whereby a whole room can be brightly illuminated.

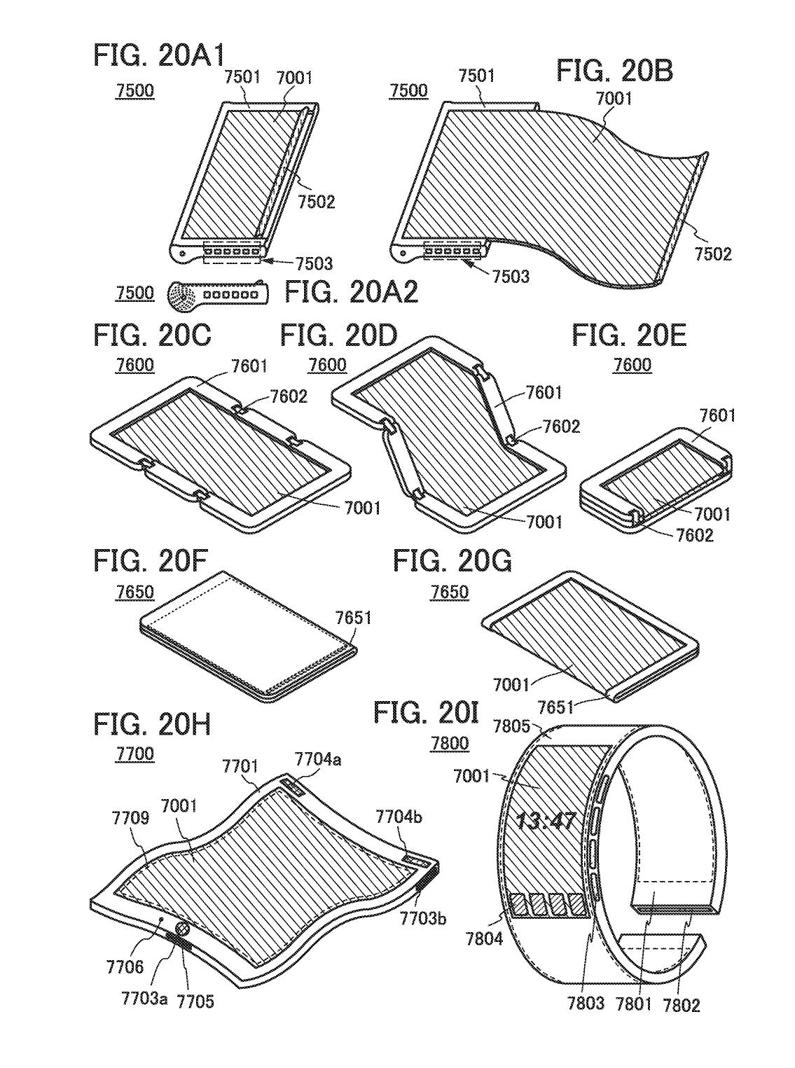

FIGS. 20A1, 20A2, and 20B to 20I each illustrate an example of a portable information terminal including a display portion 7001 having flexibility.

The display portion 7001 includes the light-emitting device, display device, or input/output device manufactured using the peeling method of one embodiment of the present invention. For example, a light-emitting device, a display device, an input/output device, or the like that can be bent with a radius of curvature of greater than or equal to 0.01 mm and less than or equal to 150 mm can be used. The display portion 7001 may include a touch sensor so that the portable information terminal can be operated by touching the display portion 7001 with a finger or the like.

According to one embodiment of the present invention, an electronic device having a flexible display portion can be provided.

FIGS. 20A1 and 20A2 are a perspective view and a side view, respectively, illustrating an example of the portable information terminal. A portable information terminal 7500 includes a housing 7501, the display portion 7001, a display portion tab 7502, operation buttons 7503, and the like.

The portable information terminal 7500 includes a rolled flexible display portion 7001 in the housing 7501. The display portion 7001 can be pulled out by using the display portion tab 7502.

The portable information terminal 7500 can receive a video signal with a control portion incorporated therein and can display the received video on the display portion 7001. The portable information terminal 7500 incorporates a battery. A terminal portion for connecting a connector may be included in the housing 7501 so that a video signal and power can be directly supplied from the outside with a wiring.

By pressing the operation buttons 7503, power on/off, switching of displayed videos, and the like can be performed. Although FIGS. 20A1, 20A2, and 20B illustrate an example where the operation buttons 7503 are positioned on a side surface of the portable information terminal 7500, one embodiment of the present invention is not limited thereto. The operation buttons 7503 may be placed on a display surface (a front surface) or a rear surface of the portable information terminal 7500.

FIG. 20B illustrates the portable information terminal 7500 in a state where the display portion 7001 is pulled out. Videos can be displayed on the display portion 7001 in this state. In addition, the portable information terminal 7500 may perform different types of display in the state where part of the display portion 7001 is rolled as illustrated in FIG. 20A1 and in the state where the display portion 7001 is pulled out as illustrated in FIG. 20B. For example, in the state illustrated in FIG. 20A1, the rolled portion of the display portion 7001 is put in a non-display state, which results in a reduction in power consumption of the portable information terminal 7500.

Note that a reinforcement frame may be provided for a side portion of the display portion 7001 so that the display portion 7001 has a flat display surface when pulled out.

Note that in addition to this structure, a speaker may be provided for the housing so that sound is output with an audio signal received together with a video signal.

FIGS. 20C to 20E illustrate an example of a foldable portable information terminal. FIG. 20C illustrates a portable information terminal 7600 that is opened. FIG. 20D illustrates the portable information terminal 7600 that is being opened or being folded. FIG. 20E illustrates the portable information terminal 7600 that is folded. The portable information terminal 7600 is highly portable when folded, and is highly browsable when opened because of a seamless large display area.

The display portion 7001 is supported by three housings 7601 joined together by hinges 7602. By folding the portable information terminal 7600 at a connection portion between two housings 7601 with the hinges 7602, the portable information terminal 7600 can be reversibly changed in shape from an opened state to a folded state.

FIGS. 20F and 20G illustrate an example of a foldable portable information terminal. FIG. 20F illustrates a portable information terminal 7650 that is folded so that the display portion 7001 is on the inside. FIG. 20G illustrates the portable information terminal 7650 that is folded so that the display portion 7001 is on the outside. The portable information terminal 7650 includes the display portion 7001 and a non-display portion 7651. When the portable information terminal 7650 is not used, the portable information terminal 7650 is folded so that the display portion 7001 is on the inside, whereby the display portion 7001 can be prevented from being contaminated and damaged.

FIG. 20H illustrates an example of a flexible portable information terminal. A portable information terminal 7700 includes a housing 7701 and the display portion 7001. In addition, the portable information terminal 7700 may include buttons 7703a and 7703b which serve as input means, speakers 7704a and 7704b which serve as sound output means, an external connection port 7705, a microphone 7706, or the like. A flexible battery 7709 can be mounted on the portable information terminal 7700. The battery 7709 may be arranged to overlap with the display portion 7001, for example.

The housing 7701, the display portion 7001, and the battery 7709 are flexible. Thus, it is easy to curve the portable information terminal 7700 into a desired shape and to twist the portable information terminal 7700. For example, the portable information terminal 7700 can be curved so that the display portion 7001 is on the inside or on the outside. Alternatively, the portable information terminal 7700 can be used in a rolled state. Since the housing 7701 and the display portion 7001 can be transformed freely in this manner, the portable information terminal 7700 is less likely to be broken even when the portable information terminal 7700 falls down or external stress is applied to the portable information terminal 7700.

The portable information terminal 7700 can be used conveniently in various situations because the portable information terminal 7700 is lightweight. For example, the portable information terminal 7700 can be used in the state where the upper portion of the housing 7701 is suspended by a clip or the like, or in the state where the housing 7701 is fixed to a wall by magnets or the like.

FIG. 20I illustrates an example of a wrist-watch-type portable information terminal. The portable information terminal 7800 includes a band 7801, the display portion 7001, an input/output terminal 7802, operation buttons 7803, and the like. The band 7801 has a function of a housing. A flexible battery 7805 can be mounted on the portable information terminal 7800. The battery 7805 may be arranged to overlap with the display portion 7001 or the band 7801, for example.

The band 7801, the display portion 7001, and the battery 7805 have flexibility. Thus, the portable information terminal 7800 can be easily curved to have a desired shape.

With the operation button 7803, a variety of functions such as time setting, on/off of the power, on/off of wireless communication, setting and cancellation of silent mode, and setting and cancellation of power saving mode can be performed. For example, the functions of the operation button 7803 can be set freely by the operating system incorporated in the portable information terminal 7800.

By touching an icon 7804 displayed on the display portion 7001 with a finger or the like, an application can be started.

The portable information terminal 7800 can employ near field communication that is a communication method based on an existing communication standard. In that case, for example, mutual communication between the portable information terminal 7800 and a headset capable of wireless communication can be performed, and thus hands-free calling is possible.

The portable information terminal 7800 may include the input/output terminal 7802. In the case where the input/output terminal 7802 is included, data can be directly transmitted to and received from another information terminal via a connector. Charging through the input/output terminal 7802 is also possible. Note that charging of the portable information terminal described as an example in this embodiment can be performed by non-contact power transmission without using the input/output terminal.

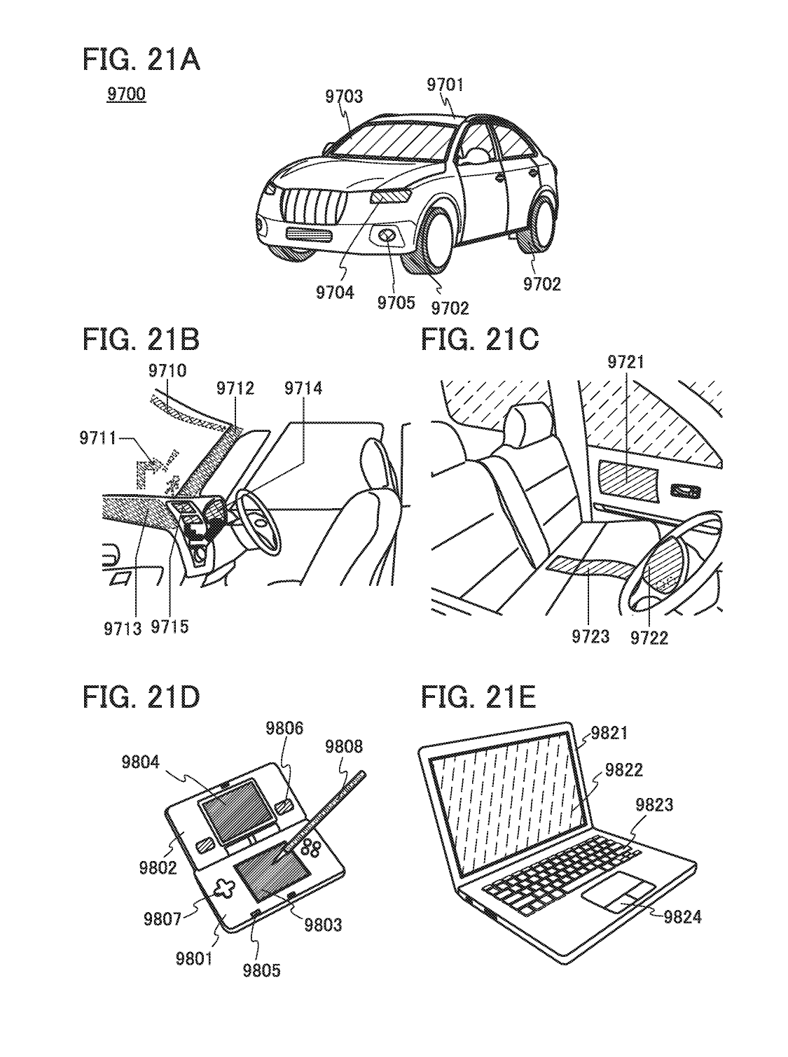

FIG. 21A is an external view of an automobile 9700. FIG. 21B illustrates a driver's seat of the automobile 9700. The automobile 9700 includes a car body 9701, wheels 9702, a windshield 9703, lights 9704, fog lamps 9705, and the like. The light-emitting device, display device, input/output device, or the like using one embodiment of the present invention can be used in a display portion of the automobile 9700. For example, the light-emitting device or the like using one embodiment of the present invention can be used in display portions 9710 to 9715 illustrated in FIG. 21B. Alternatively, the light-emitting device or the like using one embodiment of the present invention may be used in the lights 9704 or the fog lamps 9705.

The display portion 9710 and the display portion 9711 are display devices provided in the automobile windshield. The light-emitting device or the like using one embodiment of the present invention can be a see-through device, through which the opposite side can be seen, by using a light-transmitting conductive material for its electrodes and wirings. Such see-through display portions 9710 and 9711 do not hinder driver's vision during the driving of the automobile 9700. Therefore, the light-emitting device or the like using one embodiment of the present invention can be provided in the windshield of the automobile 9700. Note that in the case where a transistor or the like for driving the light-emitting device or the like is provided, a transistor having light-transmitting properties, such as an organic transistor using an organic semiconductor material or a transistor using an oxide semiconductor, is preferably used.

A display portion 9712 is a display device provided on a pillar portion. For example, the display portion 9712 can compensate for the view hindered by the pillar portion by showing an image taken by an imaging unit provided on the car body. A display portion 9713 is a display device provided on a dashboard portion. For example, an image taken by an imaging unit provided in the car body is displayed on the display portion 9713, whereby the view hindered by the dashboard can be compensated. That is, by displaying an image taken by an imaging unit provided on the outside of the automobile, blind areas can be eliminated and safety can be increased. Displaying an image to compensate for the area which a driver cannot see makes it possible for the driver to confirm safety easily and comfortably.

FIG. 21C illustrates the inside of an automobile in which a bench seat is used as a driver's seat and a front passenger seat. A display portion 9721 is a display device provided in a door portion. For example, an image taken by an imaging unit provided in the car body is displayed on the display portion 9721, whereby the view hindered by the door can be compensated. A display portion 9722 is a display device provided in a steering wheel. A display portion 9723 is a display device provided in the middle of a seating face of the bench seat. Note that the display device can be used as a seat heater by providing the display device on the seating face or backrest and by using heat generated by the display device as a heat source.

The display portion 9714, the display portion 9715, or the display portion 9722 can display a variety of kinds of information such as navigation data, a speedometer, a tachometer, a mileage, a fuel meter, a gearshift indicator, and air-condition setting. The content, layout, or the like of the display on the display portions can be changed freely by a user as appropriate. The information listed above can also be displayed on the display portions 9710 to 9713, 9721, and 9723. The display portions 9710 to 9715 and 9721 to 9723 can also be used as lighting devices. The display portions 9710 to 9715 and 9721 to 9723 can also be used as heating devices.

The flat display portion may include the light-emitting device, display device, or input/output device manufactured using the peeling method of one embodiment of the present invention.

FIG. 21D illustrates a portable game console including a housing 9801, a housing 9802, a display portion 9803, a display portion 9804, a microphone 9805, a speaker 9806, an operation key 9807, a stylus 9808, and the like.

The portable game console illustrated in FIG. 21D includes two display portions 9803 and 9804. Note that the number of display portions of an electronic device of one embodiment of the present invention is not limited to two and can be one or three or more as long as at least one display portion includes the light-emitting device, display device, input/output device, or the like using one embodiment of the present invention.

FIG. 21E illustrates a laptop personal computer, which includes a housing 9821, a display portion 9822, a keyboard 9823, a pointing device 9824, and the like.

This embodiment can be combined with any other embodiment as appropriate.

### Example 1

In this example, three kinds of samples were fabricated and their hydrogen permeability and water permeability were examined.

### [Fabrication of Samples]

Sample A was fabricated by forming an approximately 30-nm-thick tungsten film over a glass substrate by a sputtering method. The tungsten film was formed by a sputtering method under the following conditions: the flow rate of an Ar gas was 100 sccm, the power supply was 60 kW, the pressure was 2 Pa, and the substrate temperature was 100° C.

Sample B was fabricated by forming an approximately 600-nm-thick silicon oxynitride film over a glass substrate by a plasma CVD method. The silicon oxynitride film was formed by a plasma CVD method under the following conditions: the flow rates of an SiH₄ gas and an N₂O gas were 75 sccm and 1200 sccm, respectively, the power supply was 120 W, the pressure was 70 Pa, and the substrate temperature was 330° C.

Sample C was formed in the following manner: an approximately 600-nm-thick silicon oxynitride film was formed over a glass substrate by a plasma CVD method and an approximately 30-nm-thick tungsten film was formed over the silicon oxynitride film by a sputtering method. Conditions for forming the silicon oxynitride film were similar to those used for Sample B. Conditions for forming the tungsten film were similar to those used for Sample A.

### [TDS Analysis]

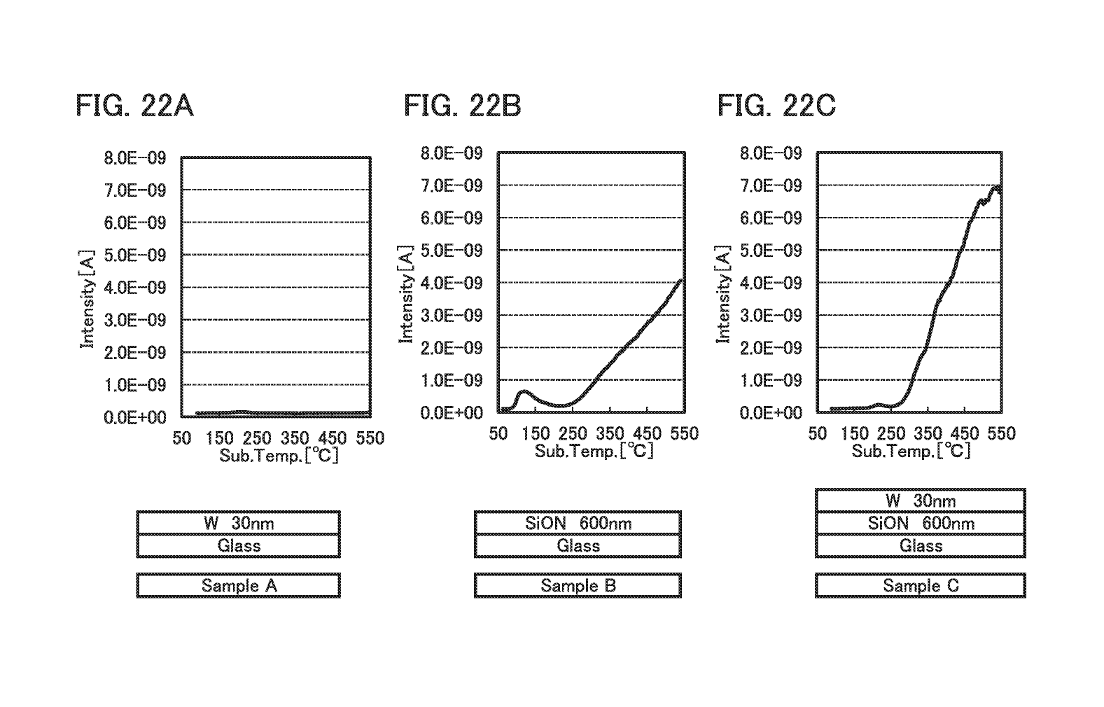

FIGS. 22A to 22C show the results of thermal desorption spectroscopy (TDS) analysis performed on Samples A to C to examine the amount of released hydrogen molecules (mass-to-charge ratio (m/z): 2) as a function of the temperature.

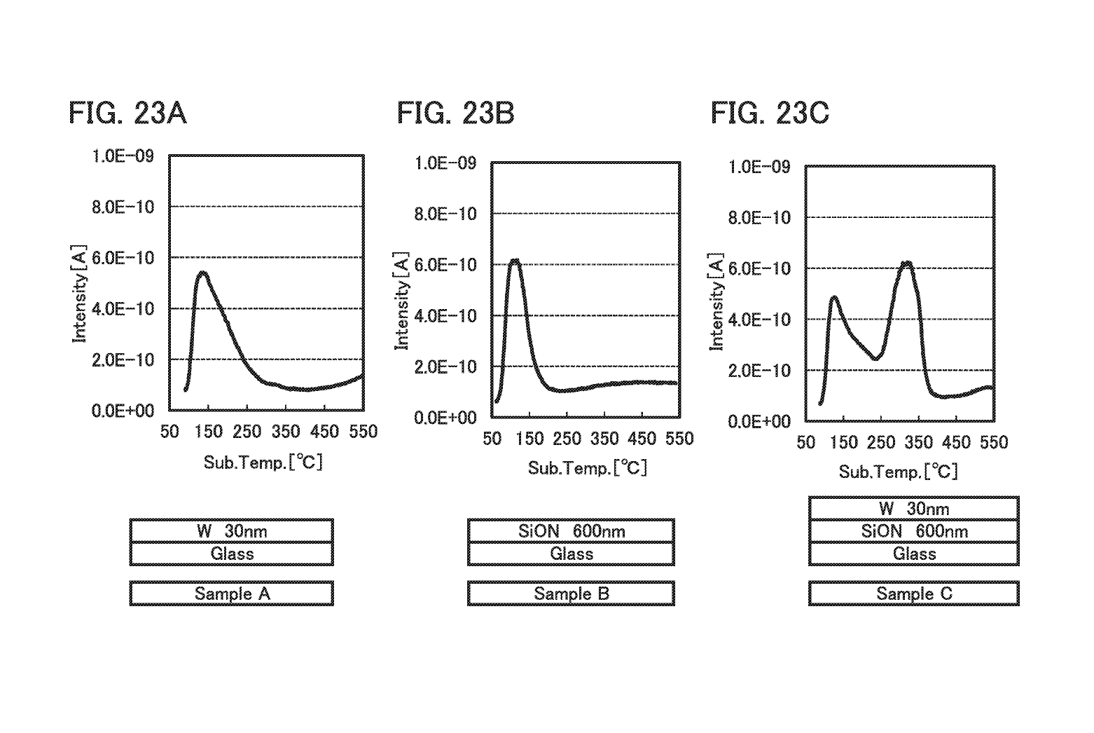

FIGS. 23A to 23C show the results of TDS analysis performed on Samples A to C to examine the amount of released water molecules (mass-to-charge ratio (m/z): 18) as a function of the temperature.

Hydrogen and water were detected from Sample B including the silicon oxynitride film. Hydrogen and water were also detected from Sample C including the tungsten film over the silicon oxynitride film.

The results in this example show that a tungsten film is permeable to hydrogen and water released from a silicon oxynitride film. In the peeling method of one embodiment of the present invention, a silicon oxynitride film is provided over a glass substrate and a tungsten film serving as a peeling layer is provided over the silicon oxynitride film. It is presumed that by heating this stacked-layer structure, hydrogen and water are released from the silicon oxynitride film, pass through the tungsten film, and reach the peeling interface.

### Example 2

In this example, peeling was performed by the peeling method of one embodiment of the present invention.

### [Fabrication of Sample 1]

A method for fabricating Sample 1 will be described with reference to FIGS. 1A to 1D and FIGS. 2A to 2C.

First, the first insulating layer 101 was formed over the formation substrate 100 (FIG. 1A).

A glass substrate was used as the formation substrate 100.

As the first insulating layer 101, an approximately 200-nm-thick silicon nitride film was formed. The silicon nitride film was formed by a plasma CVD method under the following conditions: the flow rates of an SiH₄ gas, an H₂ gas, and an NH₃ gas were 30 sccm, 800 sccm, and 300 sccm, respectively, the power supply was 600 W, the pressure was 60 Pa, and the substrate temperature was 330° C.

Next, the second insulating layer 102 was formed over the first insulating layer 101 (FIG. 1A).

As the second insulating layer 102, an approximately 600-nm-thick silicon oxynitride film was formed. The silicon oxynitride film was formed by a plasma CVD method under the following conditions: the flow rates of an SiH₄ gas and an N₂O gas were 75 sccm and 1200 sccm, respectively, the power supply was 120 W, the pressure was 70 Pa, and the substrate temperature was 330° C.

Next, the peeling layer 107 was formed over the second insulating layer 102 (FIG. 1B).

An approximately 30-nm-thick tungsten film was formed as the peeling layer 107. The tungsten film was formed by a sputtering method under the following conditions: the flow rate of an Ar gas was 100 sccm, the power supply was 60 kW, the pressure was 2 Pa, and the substrate temperature was 100° C.

Next, plasma treatment was performed on a surface of the peeling layer 107 (see the arrows indicated by dotted lines in FIG. 1C).

Specifically, the plasma treatment was performed under an atmosphere containing an N₂O gas and an SiH₄ gas. The plasma treatment was performed for 240 seconds under the following conditions: the flow rate of the N₂O gas was 1200 sccm, the flow rate of the SiH₄ gas was 5 sccm, the power supply was 120 W, the pressure was 70 Pa, and the substrate temperature was 330° C.

By the plasma treatment, an approximately 10-nm-thick silicon oxynitride film was formed over the peeling layer 107 (not shown).

Then, the third insulating layer 103 was formed over the peeling layer 107 (FIG. 1D). The element layer 104 was not formed.

As the third insulating layer 103, an approximately 200-nm-thick silicon nitride film was formed. The silicon nitride film was formed by a plasma CVD method under the following conditions: the flow rates of an SiH₄ gas, an H₂ gas, and an NH₃ gas were 30 sccm, 800 sccm, and 300 sccm, respectively, the power supply was 600 W, the pressure was 60 Pa, and the substrate temperature was 330° C.

After that, heat treatment was performed at 450° C. under a nitrogen atmosphere for 1 hour.

Then, the formation substrate 100 and the substrate 120 were bonded to each other by the bonding layer 121 (FIG. 2A). An organic resin film was used as the substrate 120. An epoxy resin was used as the bonding layer 121.

### [Fabrication of Comparative Sample 2]

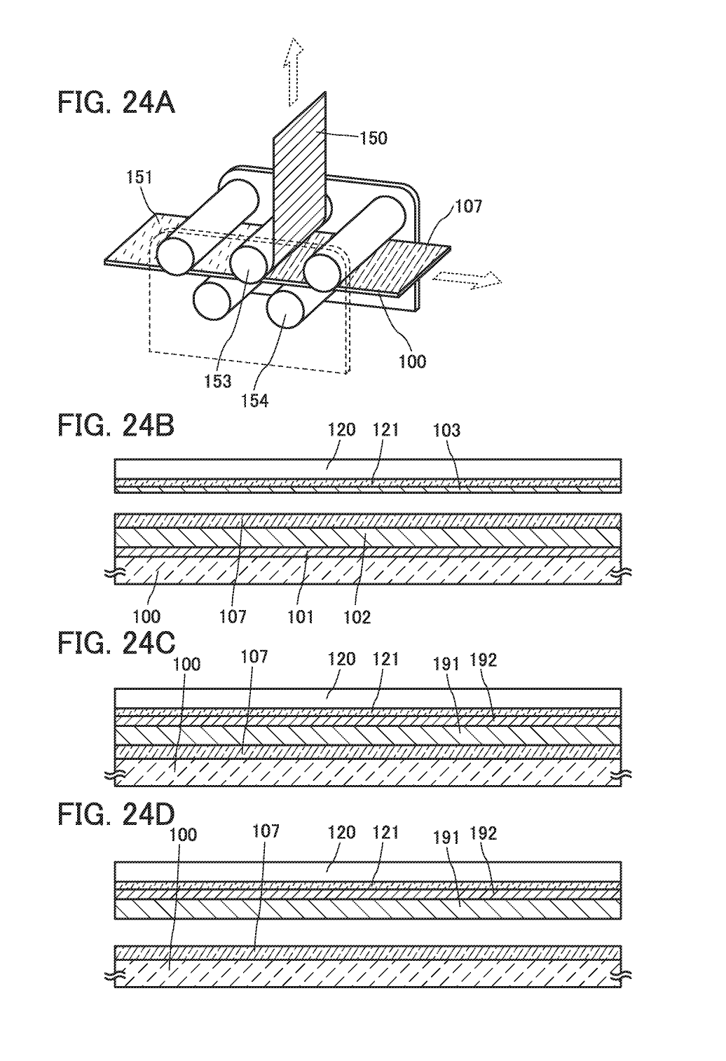

A method for fabricating Comparative Sample 2 will be described with reference to FIG. 24C.

First, the peeling layer 107 was formed over the formation substrate 100.

An approximately 30-nm-thick tungsten film was formed as the peeling layer 107. The tungsten film was formed by a sputtering method under the following conditions: the flow rate of an Ar gas was 100 sccm, the power supply was 60 kW, the pressure was 2 Pa, and the substrate temperature was 100° C.

Next, plasma treatment was performed on a surface of the peeling layer 107.

Specifically, the plasma treatment was performed under an atmosphere containing an N₂O gas and an SiH₄ gas. The plasma treatment was performed for 120 seconds under the following conditions: the flow rate of the N₂O gas was 1200 sccm, the flow rate of the SiH₄ gas was 5 sccm, the power supply was 120 W, the pressure was 70 Pa, and the substrate temperature was 330° C.

Next, a first insulating layer 191 was formed over the peeling layer 107.

As the first insulating layer 191, an approximately 600-nm-thick silicon oxynitride film was formed. The silicon oxynitride film was formed by a plasma CVD method under the following conditions: the flow rates of an SiH₄ gas and an N₂O gas were 75 sccm and 1200 sccm, respectively, the power supply was 120 W, the pressure was 70 Pa, and the substrate temperature was 330° C.

Next, a second insulating layer 192 was formed over the first insulating layer 191.

As the second insulating layer 192, an approximately 200-nm-thick silicon nitride film was formed. The silicon nitride film was formed by a plasma CVD method under the following conditions: the flow rates of an SiH₄ gas, an H₂ gas, and an NH₃ gas were 30 sccm, 800 sccm, and 300 sccm, respectively, the power supply was 600 W, the pressure was 60 Pa, and the substrate temperature was 330° C.

After that, heat treatment was performed at 450° C. under a nitrogen atmosphere for 1 hour.

Next, the formation substrate 100 and the substrate 120 were bonded to each other by the bonding layer 121. An organic resin film was used as the substrate 120. An epoxy resin was used as the bonding layer 121.

### [Peeling Test]

The force required to peel the layer to be peeled from the formation substrate 100 was measured in each of Sample 1 and Comparative Sample 2. A jig illustrated in FIG. 24A was used for the measurement. The jig illustrated in FIG. 24A includes a plurality of guide rollers 154 and a support roller 153. The measurement is as follows. First, a tape 151 is attached onto a layer 150 that includes a layer to be peeled and that has been formed over the formation substrate 100, and an end portion of the tape 151 is partly peeled in advance. Then, the formation substrate 100 is fixed to the jig so that the tape 151 is held by the support roller 153, and the tape 151 and the layer 150 including the layer to be peeled are positioned perpendicular to the formation substrate 100. The force required for peeling was measured as follows: the tape 151 was pulled at a rate of 20 mm/min in a direction perpendicular to the formation substrate 100 to peel the layer 150 including the layer to be peeled from the formation substrate 100, and the pulling force in the perpendicular direction was measured. During the peeling, the formation substrate 100 moves in the plane direction along the guide rollers 154 with the peeling layer 107 exposed. The support roller 153 and the guide rollers 154 are rotatable so that the formation substrate 100 and the layer 150 including the layer to be peeled are not affected by friction during the move.

For the peeling test, a compact table-top universal tester (EZ-TEST EZ-S-50N) manufactured by Shimadzu Corporation was used, and an adhesive tape/adhesive sheet testing method based on standard number JIS Z0237 of Japanese Industrial Standards (JIS) was employed. Each sample had a size of 126 mm×25 mm.

As illustrated in FIG. 24B, in Sample 1, separation was performed between the peeling layer 107 and the third insulating layer 103.

As illustrated in FIG. 24D, in Comparative Sample 2, separation was performed between the peeling layer 107 and the first insulating layer 191.

In the case where the force required for peeling is greater than or equal to 0.14 N, the peeled layer tends to remain on the formation substrate 100 side after the peeling test. In contrast, in the case where the force required for peeling is less than 0.14 N, favorable peeling can be performed without the peeled layer remaining on the formation substrate 100.

The force required for peeling in Sample 1 was 0.110 N and that in Comparative Sample 2 was 0.112 N. The force required for peeling is the average value obtained by measurement at 6 points of each sample.

It is found that Sample 1 in this example has peelability substantially the same as that of Comparative Sample 2, and the force required for peeling in Sample 1 is sufficiently small.

In Sample 1, the thickness of the insulating film remaining on the device side is smaller than that in Comparative Sample 2. Accordingly, the device manufactured using one embodiment of the present invention can be thin.

Note that peeling was found to be possible in Sample 1 even when the second insulating layer 102 had a thickness of approximately 200 nm or approximately 400 nm. The second insulating layer 102 is preferably thin because the time required for film formation is shortened and the productivity is increased.

The results in this example suggest that by the use of one embodiment of the present invention, a device resistant to repetitive bending and a device that can be bent with a small radius of curvature can be manufactured with a high yield.

This application is based on Japanese Patent Application serial no. 2016-052041 filed with Japan Patent Office on Mar. 16, 2016, the entire contents of which are hereby incorporated by reference.

What is claimed is:

1. A peeling method comprising the steps of:
forming a first insulating layer over a substrate;
forming a second insulating layer over the first insulating layer;
forming a peeling layer over the second insulating layer;
performing plasma treatment on a surface of the peeling layer;
forming a third insulating layer over the peeling layer;
performing heat treatment; and
separating the peeling layer and the third insulating layer from each other,
wherein the first insulating layer and the third insulating layer each comprise silicon and nitrogen, and
wherein the second insulating layer comprises silicon and oxygen.

2. The peeling method according to claim 1,
wherein the first insulating layer and the third insulating layer each comprise silicon nitride.

3. The peeling method according to claim 1,
wherein the second insulating layer comprises silicon oxynitride.

4. The peeling method according to claim 1,
wherein the first insulating layer and the third insulating layer are formed under the same film formation condition.

5. The peeling method according to claim 1,
wherein the plasma treatment is performed under an atmosphere comprising nitrous oxide.

6. The peeling method according to claim 1,
wherein the plasma treatment is performed under an atmosphere comprising nitrous oxide and silane.

7. The peeling method according to claim 1,
wherein the plasma treatment forms a fourth insulating layer over the peeling layer.

8. The peeling method according to claim 1,
wherein the plasma treatment forms an oxide layer on the peeling layer, and
wherein the oxide layer comprises at least one of materials contained in the peeling layer.

9. The peeling method according to claim 8,
wherein the peeling layer comprises tungsten, and
wherein the oxide layer comprises tungsten and oxygen by the plasma treatment.

10. A peeling method comprising the steps of:
forming a first insulating layer over a substrate;
forming a second insulating layer over the first insulating layer;
forming a peeling layer over the second insulating layer;
performing plasma treatment on a surface of the peeling layer;
forming a third insulating layer over the peeling layer;
performing heat treatment; and
separating the peeling layer and the third insulating layer from each other,
wherein the first insulating layer and the third insulating layer are each capable of blocking hydrogen, and
wherein the second insulating layer is capable of releasing hydrogen by heating.

11. The peeling method according to claim 10,
wherein the first insulating layer and the third insulating layer each comprise silicon nitride.

12. The peeling method according to claim 10,
wherein the second insulating layer comprises silicon oxynitride.

13. The peeling method according to claim 10,
wherein the first insulating layer and the third insulating layer are formed under the same film formation condition.

14. The peeling method according to claim 10,
wherein the plasma treatment is performed under an atmosphere comprising nitrous oxide.

15. The peeling method according to claim 10,
wherein the plasma treatment is performed under an atmosphere comprising nitrous oxide and silane.

16. The peeling method according to claim 10,
wherein the plasma treatment forms a fourth insulating layer over the peeling layer.

17. The peeling method according to claim 10,
wherein the plasma treatment forms an oxide layer on the peeling layer, and
wherein the oxide layer comprises at least one of materials contained in the peeling layer.

18. The peeling method according to claim 17,
wherein the peeling layer comprises tungsten, and
wherein the oxide layer comprises tungsten and oxygen by the plasma treatment.
